(19) United States
(12) Patent Application Publication
(10) Pub. No.: US 2026/0330285 A1
(43) Pub. Date: Oct. 22, 2026

(54) TWO-BIT BIT FLIPPING DECODER DIVERSITY FOR QUANTUM LDPC CODES

(71) Applicant: ARIZONA BOARD OF REGENTS ON BEHALF OF THE UNIVERSITY OF ARIZONA, Tucson, AZ (US)

(72) Inventors: Dimitris Chytas, Tucson, AZ (US); Nithin Raveendran, Tucson, AZ (US); Bane V. Vasic, Tucson, AZ (US)

(21) Appl. No.: 19/182,257

(22) Filed: Apr. 17, 2025

(51) Int. Cl. G06N 10/70; H03M 13/11

(52) U.S. Cl. CPC G06N 10/70; H03M 13/1111

(57) ABSTRACT

A method for efficient decoding of a quantum data stream. The method includes establishing a decoding threshold and identifying unique harmful substructures in the quantum data stream, each unique harmful substructure having a plurality of variable nodes, each node corresponding to a bit. The method further includes simultaneously executing a two-bit-flipping decoding pattern for each unique harmful substructure of the plurality of unique harmful substructures. The decoding pattern may be configured to increase a number of satisfied checks in the quantum data stream. The method may repeat the previous step until the decoding threshold is met or for a fixed number of iterations.

### STATEMENT REGARDING FEDERALLY SPONSORED RESEARCH OR DEVELOPMENT

This invention was made with government support under Grant Nos. 2106189, 2100013, 2027844, 2052751, and 1941583, which were awarded by the National Science Foundation. The government has certain rights in the invention.

### FIELD OF THE INVENTION

The present invention is directed to fast and efficient decoding methods for quantum low-density parity-check codes optimized for high-speed, low-latency, and computationally efficient operation in quantum computing systems.

### BACKGROUND OF THE INVENTION

Quantum low-density parity-check (QLDPC) codes have recently gained attention over topological codes due to their superior minimum distance and asymptotically scaling code rates. However, QLDPC codes require long-range qubit connections, increasing noise and adding delays, further restricting the latency available for decoding. These latency constraints are aggravated by poor error correction performance in iterative decoders like belief propagation (BP) and min-sum (MS). Iterative decoding failure is mainly attributed to inherent properties of QLDPC codes, such as degeneracy and short cycles. This degradation, particularly in the error-floor region, is prominent in low variable degree QLDPC codes, where iterative decoding fails to correct low-weight error patterns that occur within harmful configurations known as trapping sets.

Several approaches modify message-passing rules or scheduling to break the symmetries imposed by symmetric stabilizers and improve performance. Prior systems introduced heuristic modifications to BP, including freezing, random perturbation, and collision, which enhanced performance for degenerate codes but are non-deterministic and do not exploit the code structure. BP with bias using Oscillating Trapping Sets (BP-OTS) improves performance by modifying decoding rules for trapping sets in topological codes, though it has not been demonstrated for other QLDPC families. Layered BP and MS algorithms exploit degeneracy to improve performance, but their serial nature increases latency. Advanced post-processing techniques, such as ordered statistics decoding (OSD), stabilizer inactivation (SI), and BP with guided decimation, can further improve performance but at the cost of high complexity (O(n³), O(n² log(n)), and O(n²), respectively), where n is the blocklength of the code.

Recently, additional post-processing techniques have been introduced to improve the efficiency of solving the matrix inversion problem in BP-OSD. The ambiguity clustering method constructs a dynamic block or cluster structure within the parity-check matrix, enabling the decoder to address ambiguities by concentrating on localized error regions rather than tackling the entire system simultaneously. Similarly, localized statistics decoding operates on disconnected subgraphs (or clusters) where errors are likely to occur, processing them independently and in parallel, although its complexity scales cubically with cluster size. Furthermore, recent advancements have integrated post-processing methods tailored to more accurate noise models, such as BP combined with ordered Tanner forest (BP+OTF), sliding window BPGD decoding, and the SymBreak decoder.

Bit Flip (BF) decoding is a low-complexity alternative widely used in classical LDPC decoding due to its good trade-offs between performance and complexity. Several BF variants have been proposed for quantum error correction (QEC). The small-set-flip (SSF) decoder addresses degeneracy by flipping sets of bits within stabilizers rather than single bits, introducing asymmetry that helps decode degenerate errors. However, SSF requires large codes to be effective and is not guaranteed to correct errors within trapping sets. SSF has also been used as a post-processing technique following BP to reduce error weight before SSF decoding. The Turbo-XZ algorithm applies BF with iteration-dependent thresholds to correct error patterns in trapping sets but does not fully exploit degeneracy. BF methods have also been applied to topological codes, such as progressive-proximity BF, which leverages structural properties for decoding.

The concept of collective decoding has been previously explored in classical and quantum error correction literature. In classical setting, a set of diverse low-complexity decoders operating in parallel achieves guaranteed error correction performance in a bounded number of iterations. Relating to QEC, collective BP decoding was used within the framework of deep neural network-based learning wherein a trapping set-based importance sampling approach is used to learn new decoding rules. However, existing approaches are either computationally intensive or unsuitable for real-time quantum error correction. Thus, there exists a present need for a fast approach to implementing collective bit-flipping decoding for real-time operation on the quantum measurement data streams.

### BRIEF SUMMARY OF THE INVENTION

It is an objective of the present invention to provide systems, methods, and non-transitory computing media that allow for fast and efficient decoding for quantum computing, as specified in the independent claims. Embodiments of the invention are given in the dependent claims. Embodiments of the present invention can be freely combined with each other if they are not mutually exclusive.

The present invention builds on BF but distinguishes itself by specifically targeting low-latency decoding with guaranteed correction of error patterns in specific QLDPC code structures. Two-bit bit flipping (TBF) decoding is implemented, which has shown superior performance over original BF decoding. The invention develops syndrome-based TBF decoding for QLDPC codes that assigns more states to both variable and check nodes, allowing for higher granularity in variable node processing, thus enhancing error correction. Unlike alternatives like gradient-descent bit flipping (GDBF) and its probabilistic versions, TBF uses low-complexity deterministic functions, facilitating both analytical tractability, simplified hardware or software implementation, and seamless integration into a collective decoding framework.

One of the unique and inventive technical features of the present invention is the implementation of a plurality of simple decoding modules running in parallel for two-bit bit flipping. Without wishing to limit the invention to any theory or mechanism, it is believed that the technical feature of the present invention advantageously provides for efficient, speedy, and accurate decoding of data streams for quantum computing. None of the presently known prior references or works have the unique inventive technical feature of the present invention.

Moreover, the technical feature of the present invention contributed to a surprising result. For example, one of ordinary skill in the art would implement a single complex decoder able to decode a wide variety of different harmful substructures. The presently claimed invention implements a plurality of simple decoders each configured to handle certain kinds of harmful substructures all in parallel. Surprisingly, this is more time and memory efficient than implementing only one decoder. Thus, the technical feature of the present invention contributed to a surprising result.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1A shows a graphical representation of a (3,3) trapping set. Each child of the (3, 3) trapping set is a juxtaposition of two, three, and four six-cycles, respectively. Odd-degree check nodes are represented by black blocks.

FIG. 1B shows a graphical representation of a (5,5) trapping set. Odd-degree check nodes are represented by black blocks.

FIG. 1C shows a graphical representation of a (6,4) trapping set. Odd-degree check nodes are represented by black blocks.

FIG. 1D shows a graphical representation of a (8,6) trapping set. Odd-degree check nodes are represented by black blocks.

FIG. 2A shows a graphical representation of a (63,63) trapping set obtained by the (3,3) trapping set in the B^{T} circulant matrix. B^{T} contains seven (63,63) trapping sets. (63,63) trapping sets are only interconnected with (49,49) trapping sets. Only degree-3 check nodes appear in the trapping sets. Two styles of dotted lines are used to represent connections between remote nodes. The five 6-cycles in a row can be inferred from the polynomial 1+x+x⁶.

FIG. 2B shows a graphical representation of a (49,49) trapping set obtained by the (3,3) trapping set in the A^{T} circulant matrix. A^{T} contains nine (49,49) trapping sets. (49,49) trapping sets are only interconnected with (63,63) trapping sets. Only degree-3 check nodes appear in the trapping sets. Two styles of dotted lines are used to represent connections between remote nodes.

FIG. 3A shows a graphical representation of a (4,4) trapping set.

FIG. 3B shows a graphical representation of a (5,3) trapping set obtained after adding a single variable node to the trapping set of FIG. 3A.

FIG. 3C shows a graphical representation of a symmetric stabilizer comprising a (6,0) trapping set obtained after adding another variable node to the trapping set of FIG. 3A. The three line types used for the (6, 0) trapping set indicate that the lines do not overlap. Notice that variable nodes belonging to different circulant matrices are connected via one check node.

FIG. 4 shows an overview of the structure of B1 code. The symmetric stabilizer interconnects the two types of trapping sets. The (63, 63) and (49, 49) trapping sets are represented as yellow and green circles, respectively, which indicate their symmetric structure.

FIGS. 5A-5D show the evolution of the decoding procedure for a (3,3) trapping set for an instance of TBF decoding, where the flags W₂₀₁=1 and W₁₁₁=1 are enabled. The (3, 3) trapping set is considered to be a part of the (63, 63) trapping set. Each figure corresponds to the state of the decoder for each iteration. Light gray and dark gray colored circle nodes correspond to weak zeros and weak ones respectively, whereas black colored squares correspond to unsatisfied checks. Flag W₂₀₁ initially flips all nodes in the support of unsatisfied checks and flag W₁₁₁ prevents the bit v₁₈ from being flipped during the third iteration. As a result, the algorithm converges in four iterations.

FIGS. 6A-6E show uncorrectable weight-3 error configurations by BF decoder. These errors appear in smaller trapping sets within the (63, 63) and (49, 49) trapping sets. Variable nodes in error are marked with black circles. Note that in this case, a black rectangle corresponds to an unsatisfied check.

FIGS. 7A-7C show a progression of BF algorithm for a weight-3 error pattern appearing inside the (6, 0) trapping set. FIG. 7A represents the initial state of the decoder, and the error pattern is marked with gray. After every node with two unsatisfied checks has been flipped, the graph in FIG. 7B is obtained, and then BF oscillates between states depicted in FIG. 7B and FIG. 7C, as it always flips the same number of nodes belonging to the two different circulants. Such an error configuration can be resolved by treating nodes of different circulant matrices differently, thus inducing asymmetry.

FIG. 8 shows a graph of the performance of collective bit flipping-based decoding for the B1 code. D₄ surpasses nMS decoding while D₂₄ also surpasses layered nMS decoding in the error-floor region.

FIG. 9 shows a graph of the performance of collective bit flipping-based decoding for the B3 code. D₂₄ surpasses nMS decoding. The set of proposed decoders provides better performance than that of the B1 code (for which it was originally designed for) due to the sparsity that the B3 code offers.

FIG. 10 shows a graph of the performance of collective bit flipping-based decoding for the BB code. The ensemble of 24 decoders outperforms the nMS algorithm. BDD (288,8) performance is also included for comparison.

FIG. 11 shows a graph of the average number of iterations required by nMS and D₂₄ for decoding the B3 code.

FIG. 12 shows a graph of the performance of SSF for the family of BB codes. Decoding performance deteriorates as distance increases, and no threshold is achieved.

FIG. 13 shows a graph of the decoding performance of the ensemble of 24 decoders for the family of BB codes. D₂₄, which is designed to correct up to weight-5 errors appearing in (49, 49) and (63, 63) trapping sets, achieves a threshold approximating 3%.

FIG. 14 shows a table describing Ψ which assigns the state of a variable node v at the (l+1)^{th} iteration based on its current state wᵥⁱ and the number of its current adjacent unsatisfied checks

$${X}_{1}^{l} ( v ) .$$

FIG. 15 shows a table of a set of eight TBF decoders that guarantee the correction of all error patterns up to weight-5 that appear inside the (49, 49) and (63, 63) trapping sets of the B1 code (children of the (3, 3) trapping set). All decoders share the same Ψ function.

FIG. 16 shows a table of a realization of the Ψ function, which is only applied on variable nodes of one circulant matrix and in conjunction with the update rule described by FIG. 14 corrects error patterns inside quantum trapping sets.

FIG. 17 shows a comparison of BF, TBF, and MS decoding based on memory and operational complexity per iteration.

FIG. 18 shows a comparison of average logical error rates for D₂₄ and SSF decoders on random HP codes (dᵥ=3, d_{c}=6) over a BSC with crossover probability p=0.01. Results are averaged over 50 random codes, showing improved performance of our framework as the blocklength increases.

FIG. 19A shows a schematic diagram of a system for efficient decoding of quantum data of the present invention.

FIG. 19B shows a flow chart of a method for efficient decoding of quantum data of the present invention.

FIG. 19C shows a schematic diagram of a non-transitory computing medium for efficient decoding of quantum data of the present invention.

FIG. 19D shows a schematic diagram of an alternate system for efficient decoding of quantum data of the present invention.

### DETAILED DESCRIPTION OF THE INVENTION

Following is a list of elements corresponding to a particular element referred to herein:
100 system
110 processor
120 memory component
500 system
510 decoders
520 controller
530 selection module
540 output interface

The term “unsatisfied checks” is defined herein as flagged syndrome bits that are determined by the syndrome measurement. The goal of the decoder is to estimate a codeword, which is a configuration of bits that satisfies all the checks.

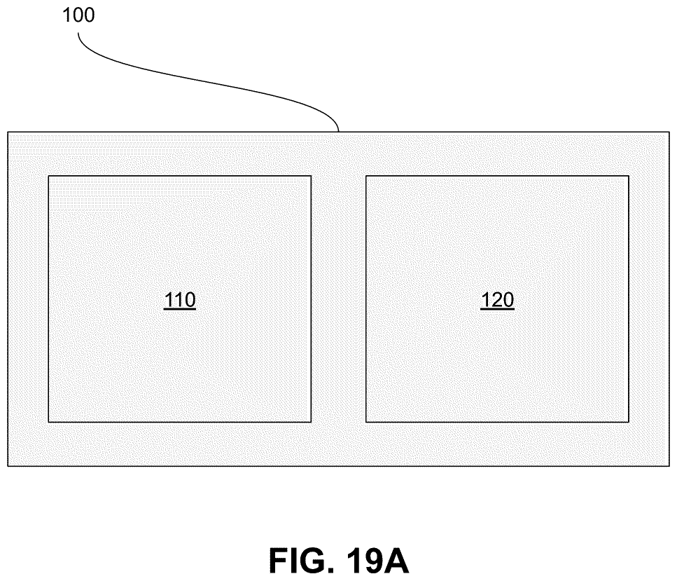

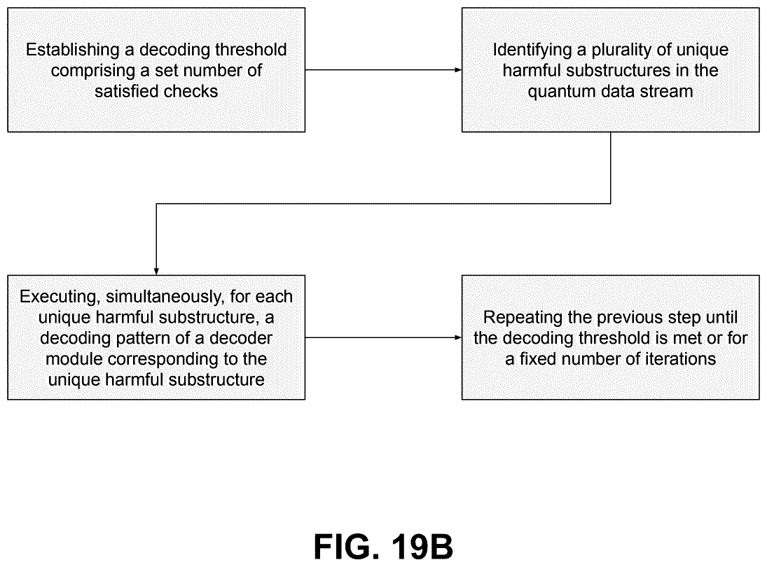

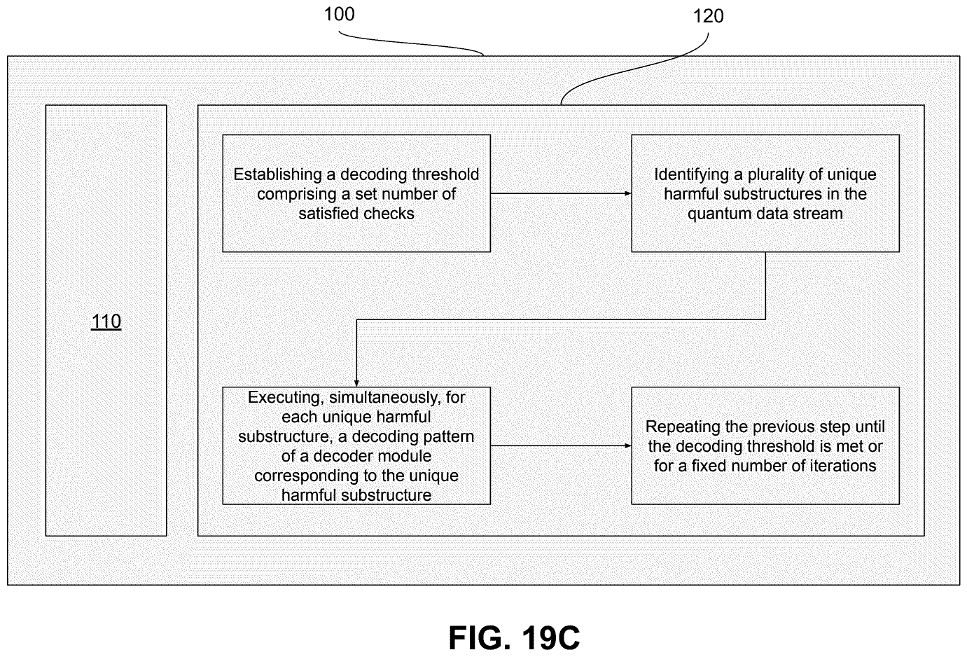

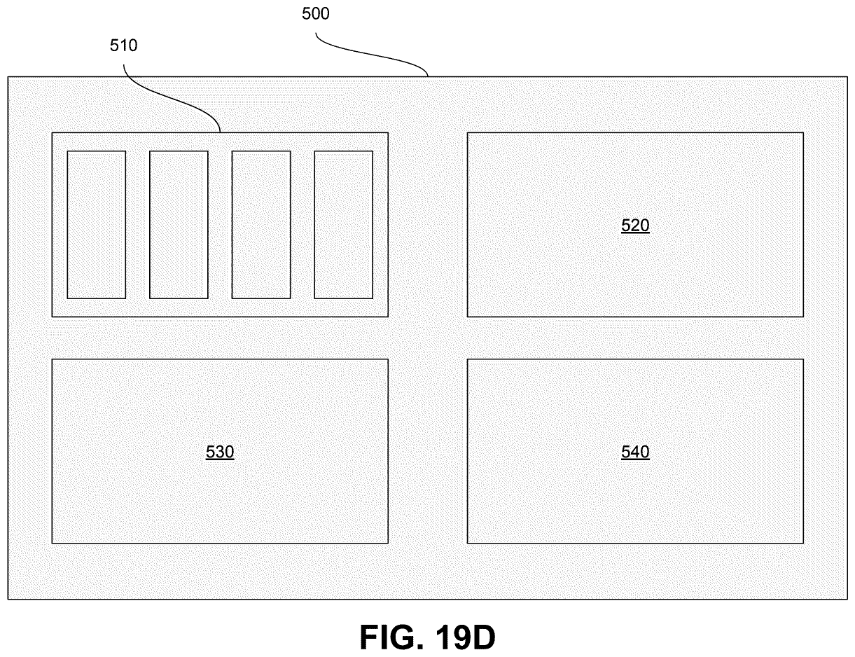

Referring now to FIG. 19A, the present invention features a system (100) for efficient decoding of a quantum data stream. In some embodiments, the system (100) may comprise a processor (110) configured to execute computer-readable instructions. The system (100) may further comprise a memory component (120) operatively coupled to the processor (110). The memory component (120) may comprise a plurality of decoder modules, each decoder module configured to execute a decoding pattern corresponding to a unique harmful substructure in the quantum data stream. The unique harmful substructure may comprise a plurality of variable nodes, each node corresponding to a bit. The decoding pattern may comprise labelling one or more nodes of the plurality of nodes as weak nodes, labelling all remaining nodes of the plurality of nodes as strong nodes, and accordingly flipping the bits of both strong and weak nodes based on the assigned rules. The decoding pattern may be configured to increase a number of satisfied checks in the quantum data stream. Decoding is successful when all checks are satisfied.

The memory component (120) may further comprise computer-readable instructions for establishing a decoding threshold comprising a set number of satisfied checks. The computer-readable instructions may further comprise identifying a plurality of unique harmful substructures in the quantum data stream. The computer-readable instructions may further comprise executing, simultaneously, for each unique harmful substructure of the plurality of unique harmful substructures, the decoding pattern of a decoder module of the plurality of decoder modules corresponding to the unique harmful substructure of the plurality of unique harmful substructures. The computer-readable instructions may further comprise repeating the previous step until the decoding threshold is met such that all checks are satisfied or for a fixed number of iterations.

In some embodiments, the unique harmful substructure may further comprise one or more check nodes. In some embodiments, each decoder module may implement a two-bit flipping (TBF) decoding algorithm. Variable nodes and check nodes may be assigned multiple discrete internal states, and bit flipping decisions are made deterministically based on these states. In some embodiments, the weak nodes may represent nodes connected to a number of unsatisfied checks below a node strength threshold. In some embodiments, the strong nodes may represent nodes connected to a number of unsatisfied checks above a node strength threshold. In some embodiments, the plurality of unique harmful substructures may comprise (3,3) trapping sets, (5,5) trapping sets, (6,4) trapping sets, (8,6) trapping sets, (63,63) trapping sets, (49,49) trapping sets, or a combination thereof. In some embodiments, the fixed number of iterations may comprise 10 to 20 iterations.

Referring now to FIG. 19B, the present invention features a computer-implemented method for efficient decoding of a quantum data stream. The method may comprise establishing a decoding threshold comprising a set number of satisfied checks. The method may further comprise identifying a plurality of unique harmful substructures in the quantum data stream, each unique harmful substructure comprising a plurality of variable nodes, each node corresponding to a bit. The method may further comprise executing, simultaneously, for each unique harmful substructure of the plurality of unique harmful substructures, a decoding pattern of a decoder module of a plurality of decoder modules corresponding to the unique harmful substructure of the plurality of unique harmful substructure. The decoding pattern may comprise labelling one or more nodes of the plurality of nodes as weak nodes, labelling all remaining nodes of the plurality of nodes as strong nodes, and flipping the bit of each node according to the unique harmful structure. The decoding pattern may be configured to increase a number of satisfied checks in the quantum data stream. The method may further comprise repeating the previous step until the decoding threshold is met such that all checks are satisfied or for a fixed number of iterations.

In some embodiments, the unique harmful substructure may further comprise one or more check nodes. In some embodiments, check node updates may incorporate multi-state logic to track consistency and improve correction granularity. In some embodiments, the weak nodes may represent nodes connected to a number of unsatisfied checks below a node strength threshold. In some embodiments, the strong nodes may represent nodes connected to a number of unsatisfied checks above a node strength threshold. In some embodiments, the plurality of unique harmful substructures may comprise (3,3) trapping sets, (5,5) trapping sets, (6,4) trapping sets, (8,6) trapping sets, (63,63) trapping sets, (49,49) trapping sets, or a combination thereof. In some embodiments, the fixed number of iterations may comprise 10 to 20 iterations. In some embodiments, the decoding pattern may comprise assigning two or more discrete state values to each variable node to represent varying levels of confidence, and flipping bits deterministically based on these states.

Referring now to FIG. 19C, the present invention features a non-transitory computing medium (120) comprising computer-readable instructions. When executed on a processor (110), the computer-readable instructions may be configured to cause the processor (110) to establish a decoding threshold comprising a set number of satisfied checks. The computer-readable instructions may be further configured to cause the processor (110) to identify a plurality of unique harmful substructures in a quantum data stream, each unique harmful substructure comprising a plurality of variable nodes, each node corresponding to a bit. The computer-readable instructions may be further configured to cause the processor (110) to execute, simultaneously, for each unique harmful substructure of the plurality of unique harmful substructures, a decoding pattern of a decoder module of a plurality of decoder modules corresponding to the unique harmful substructure of the plurality of unique harmful substructure. The decoding pattern may comprise labelling one or more nodes of the plurality of nodes as weak nodes, labelling all remaining nodes of the plurality of nodes as strong nodes, and flipping the bit of each node according to the unique harmful structure. The decoding pattern may be configured to increase a number of satisfied checks in the quantum data stream. The computer-readable instructions may be further configured to cause the processor (110) to repeat the previous step until the decoding threshold is met such that all checks are satisfied or for a fixed number of iterations.

In some embodiments, the unique harmful substructure may further comprise one or more check nodes. In some embodiments, the weak nodes may represent nodes connected to a number of unsatisfied checks below a node strength threshold. In some embodiments, the strong nodes may represent nodes connected to a number of unsatisfied checks above a node strength threshold. In some embodiments, the plurality of unique harmful substructures may comprise (3,3) trapping sets, (5,5) trapping sets, (6,4) trapping sets, (8,6) trapping sets, (63,63) trapping sets, (49,49) trapping sets, or a combination thereof. In some embodiments, the fixed number of iterations may comprise 10 to 20 iterations.

Referring now to FIG. 19D, the present invention features a system (500) for collective decoding of quantum low-density parity-check (QLDPC) codes. In some embodiments, the system (500) may comprise a plurality of two-bit flipping (TBF) decoders (510), each configured with a distinct set of deterministic update rules and node state mappings. The system (500) may further comprise a controller (520) configured to execute the TBF decoders (510) in parallel on a common quantum syndrome derived from quantum measurements. The system (500) may further comprise a selection module (530) configured to determine a preferred decoding output based on a convergence metric, syndrome weight, or decoding stability. The system (500) may further comprise an output interface (540) configured to return the selected decoding result as the corrected codeword estimate.

In some embodiments, the distinct set of deterministic update rules and node state mappings may comprise identifying one or more weak nodes and one or more strong nodes. In some embodiments, the weak nodes may represent nodes connected to a number of unsatisfied checks below a node strength threshold. In some embodiments, the strong nodes may represent nodes connected to a number of unsatisfied checks above a node strength threshold. In some embodiments, the selection module (530) may be configured to identify (3,3) trapping sets, (5,5) trapping sets, (6,4) trapping sets, (8,6) trapping sets, (63,63) trapping sets, (49,49) trapping sets, or a combination thereof.

### EXAMPLE

The following is a non-limiting example of the present invention. It is to be understood that said example is not intended to limit the present invention in any way. Equivalents or substitutes are within the scope of the present invention.

The collective decoding approach of the present invention is described herein. Two major types of harmful configurations impede iterative decoding, namely, classical and quantum trapping sets (or symmetric stabilizers). Hence, the decoding framework should be able to deal with error patterns that appear in those two configurations. The present approach was to first enumerate harmful configurations by using the shortest cycles of the code as a starting point and then exploit the parent-child relationships of these graphs in order to obtain the most dominant harmful graphs. After the enumeration process, the goal was to develop a set of diverse TBF decoders capable of decoding all error patterns within quantum trapping sets and all error patterns up to a certain weight within classical trapping sets.

The present focus was on variable degree-3 (dᵥ₋₃) QLDPC codes from the generalized hypergraph product (GHP) code family. GHP codes suffer from error-floor under iterative decoding, which performs poorly despite the large distance of the codes. Nevertheless, this family of codes achieved higher distance when compared to hypergraph product (HP) codes. Also, when GHPs were decoded with BP-OSD, they achieved better performance, free of error-floor, than HP codes. This fact demonstrated the potential of this family of codes and enabled analysis of them. The restriction of the variable node degree was only for the sake of analysis, and the method is extendable to higher variable node degree codes. Interestingly, it was observed that for a family of dᵥ₋₃ QLDPC codes, the 6-cycles led to classical trapping sets, which were only interconnected by quantum trapping sets, which in turn emerged from the 8-cycles. Such analysis provided an overview of the structure of dᵥ₋₃ QLDPC codes. Based on the knowledge of harmful structures in this family of codes, a systematic method of generating the set of TBF decoders was determined, able to collectively correct low-weight error patterns appearing inside both classical and quantum trapping sets.

Finally, simulation results are provided featuring the selected set of TBF decoders, and it was shown that it surpassed the performance of message-passing decoders such as MS and layered MS for three different dᵥ₋₃ QLDPC codes.

Consider the n-fold Pauli group, Gₙ [symbol] {pP₁⊗ . . . ⊗PPₙ: p∈{±1, ±i}, Pⱼ∈{I, X, Y, Z}}, where I, X, Y, and Z are called Pauli operators. Every element in Gₙ has eigenvalues ±1, and any two elements in Gₙ either commute or anticommute with each other. A stabilizer group S is an Abelian subgroup in Gₙ that does not contain −l. If S is generated by n-k independent generators, it defines a stabilizer code C that encodes k logical qubits into n physical qubits, with dₘᵢₙ being its minimum distance. The elements of S are called stabilizers. The set of generators of S can be represented by the stabilizer matrix H, whose (i, j)^{th} element is given by the Pauli operator corresponding to the j^{th} qubit in the i^{th} stabilizer.

By applying the binary mapping to the stabilizer matrix, S, a (n-k)×2n binary matrix was obtained: H=[HZ|HX] (Equation 1), which we call the parity check matrix of C. Since the corresponding stabilizers of S commute with each other, it was verified that:

$$H \times {H}_{Z}^{T} + {H}_{Z} {H}_{X}^{T} = 0 . \qquad ( Equation 2 )$$

HP codes constitute a class of Calderbank-Shor-Steane (CSS) codes. A CSS code is a stabilizer code constructed using two classical codes, C_{X}[n, k_{X}, dₘᵢₙ,x] and C_{Z}[n, k_{Z}, d_{min,Z}], where dₘᵢₙ≥min{d_{min,X}, d_{min,Z}} and C_{Z}⊆≤C_{X}. Given the stabilizer matrix H_{X} of C_{X} and H_{Z} of

$${C}_{Z}^{⊥} ,$$

the CSS code constructed from C_{X} and C_{Z} had the form

$$H = [ \begin{matrix}{H}_{Z} & 0 \\ 0 & {H}_{X}\end{matrix} ] ,$$

$$where {H}_{X} {H}_{Z}^{T} = 0$$

(unless specified otherwise, it was assumed all operations on binary matrices and vectors are performed on the binary field).

CSS codes facilitate binary decoding because of their structure, i.e., X errors are decoded using H_{Z}, and Z errors are decoded using H_{X}. Therefore, one can consider the two independent binary symmetric channels (BSCs) rather than the depolarizing channel, thus ignoring the correlation between the X and Z errors. e=[e_{X}, e_{Z}] the binary representation of a Pauli error acting on the n qubits. The corresponding input syndromes are obtained as

$${s}_{Z} = {e}_{Z} {H}_{X}^{T} and {s}_{X} = {e}_{Z} {H}_{X}^{T} ,$$

or in a compact form, s=[s_{X}, s_{Z}].

An all-zero syndrome vector indicated that all stabilizers commuted with the error pattern. On the other hand, when the syndrome vector was non-zero, an error was detected. The goal of the syndrome-based decoder was to produce an estimate error pattern ê, which corresponds to a syndrome ŝ that matches s. A decoding success was observed if the initial error e was recovered up to a stabilizer, which meant that e ⊗ ê belonged to the rowspace of the parity check matrix H. Error correction was unsuccessful when the decoder was not able to match the input syndrome s, or when the decoding process resulted in a logical error, such that e ⊗ ê commuted with all the stabilizers, but was not in the rowspace of H.

The H_{X} and H_{Z} stabilizer matrices can each be represented as a Tanner graph, denoted as G, which is a bipartite graph with two sets of nodes: n variable (qubit) nodes V={v₁, . . . , vₙ} and m check nodes C={c₁, . . . , cₘ}. The set of edges (non-zero entries of the stabilizer matrix) connecting the two sets of nodes is denoted as E. For a subset of nodes V₁⊆V, N (V₁) denotes the set of its check node neighbors. The induced sub-graph of V₁ is the graph containing the nodes V₁UN (V₁) along with the edges that connect the two sets. The degree of a node is the number of its neighbors. A dᵥ-variable-regular LDPC code has a Tanner graph in which all variable nodes have the same degree, dᵥ. The degree of a check node c is denoted by d_{c}. For a Tanner graph G, the girth g is the length of the shortest cycle in G. H refers to H_{Z}, e refers to e_{X}, and s refers to s_{Z}.

The syndrome-based version of the parallel BF algorithm was a simple hard decision decoder for LDPC codes on the BSC. The decoder iterated until the input syndrome was matched or a maximum of L iterations was reached. Each check node c∈C was satisfied if its estimated syndrome [symbol] matches the input s_{c}; otherwise, it was unsatisfied, with residual syndrome r_{c} calculated as their XOR. In each iteration, the algorithm flipped variable nodes connected to more unsatisfied than satisfied check nodes, i.e., flips v if

$${X}_{I}^{l} ( 1 ) > \frac{{d}_{v}}{2} , where {X}_{0}^{l} ( v ) and {X}_{1}^{l} ( v )$$

represent the number of satisfied and unsatisfied checks connected to v at the start of iteration I. For regular QLDPC codes, dᵥ was uniform for each v∈V. To adapt to quantum decoding, a syndrome-based BF decoder that iteratively flipped variable nodes to find an error pattern ê with syndrome ŝ=êH^{T} matching s can be used.

In general, the failures of BF decoding were characterized by the notion of trapping sets. According to the quantum decoding problem, a variable node v is said to be eventually converged if there exists a positive integer I such that for all l≥I,

$${\hat{e}}_{v}^{l} = {\hat{e}}_{v}^{l - 1} .$$

Also, a check node c was eventually satisfied if there existed a positive integer I such that for all I≥I,

$${\hat{s}}_{c}^{l} = {s}_{c} .$$

A set or variable-nodes T is a trapping set, if there exists an error syndrome s, such that when the syndrome-based decoder is executed on s, any variable-node in T is either not-eventually converged or a neighbor of a not-eventually satisfied check (or both).

If the sub-graph induced by the set of variable nodes T contained a variable node and b odd-degree check nodes, then T was labeled as a (a, b) trapping set. As in the Tanner graph representation, the variable nodes and check nodes of the trapping set-induced sub-graph were represented by circular and square nodes, respectively. The odd-degree check nodes were shown using black-shaded square nodes. The level of harmfulness of a trapping set under a certain decoder was characterized by its critical number. A critical number of a trapping set is the minimal number of variable nodes that have to be initially in error for the decoder to fail to converge. The set of variable nodes that have to be initially in error for the decoder to fail to converge is called a failure inducing set.

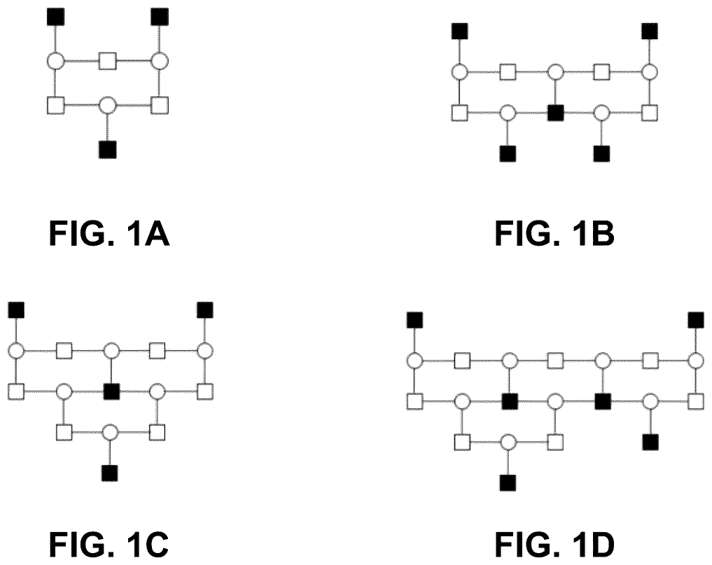

A particular family of trapping sets, i.e., fixed sets, were detrimental to the BF decoding performance. A trapping set was considered to be a fixed set or fixed point of the bit flipping algorithm if the hard decision of the set of variable nodes T remained unchanged after the first round of decoding. It was also observed that for T to be a fixed set, no variable node v∈T should be connected to more odd-degree than even-degree checks. If a fixed set containing a variable node existed, then BF decoding was not guaranteed to correct all error patterns up to a errors. Examples of fixed sets apparent in families of GHP codes are shown in FIGS. 1A and 1C, respectively.

The quantum decoding problem introduced another type of harmful configuration, as the decoder needed to converge to an estimate error pattern ê such that ê ⊗ e is a stabilizer. This differed from the classical decoding problem where an exact match of error was required. Error vectors were referred to as e and f as degenerate errors if e ⊗ f was a stabilizer. Hence, it was equivalent to output any one of the degenerate errors as the candidate error pattern for matching the syndrome. However, in QLDPC codes whose minimum distance was higher than their stabilizer weight, certain degenerate errors impeded iterative decoding. A symmetric topology of the stabilizer sub-graph that contained degenerate error patterns e and f of equal weight resulted in a decoding failure. This failure was caused by the symmetry of both the stabilizer and the iterative decoder update rules. Hence, such errors were referred to as symmetric degenerate errors, and the corresponding sets of variable nodes as symmetric stabilizers or quantum trapping sets.

A symmetric stabilizer is a stabilizer with a set of variable/qubit nodes whose induced sub-graph has no odd-degree check nodes, and that can be partitioned into an even number of disjoint subsets so that (a) sub-graphs induced by these subsets of variable nodes are isomorphic, and (b) each subset has the same set of odd-degree check node neighbors in its induced sub-graph.

Assuming that a code has girth g, it is well known that the shortest cycles of the code, namely the ones with length g and g+2, constitute trapping sets for iterative decoding algorithms. Therefore, a way to obtain larger configurations that are harmful to decoding was to exploit the parent-child relationship between trapping sets. A trapping set T₁ is a parent of T₂ (or that T₂ is a child of T₁) if T₂ contained a subset whose induced sub-graph was isomorphic to T1.

HP codes are a family of QLDPC codes constructed by the hypergraph product of any two classical codes. Here, GHP codes that contain both generalized bicycle codes and the class of HP codes, where one of the two parity-check matrices used in the product is square, were focused on. The analysis was based on enumerating trapping sets that were children of the g− and (g+2)-cycles of the code. To search for the children trapping sets, the g-cycles of the code were considered to be the parent trapping sets. In general, the effectiveness of a decoder was determined by the lowest weight error patterns it failed to correct and the frequency of these failures. Larger trapping sets, formed by adding variable nodes to a smaller (parent) trapping set, often had lower critical numbers and introduced additional failure inducing sets, making them more challenging to correct.

The B1 GHP code is used as a case study for the upcoming analysis. The A and B matrices that describe the B1 code are given below:

$$A = ( \begin{matrix}{x}^{27} & 0 & 0 & 0 & 0 & 1 & {x}^{54} \\ {x}^{54} & {x}^{27} & 0 & 0 & 0 & 0 & 1 \\ 1 & {x}^{54} & {x}^{27} & 0 & 0 & 0 & 0 \\ 0 & 1 & {x}^{54} & {x}^{27} & 0 & 0 & 0 \\ 0 & 0 & 1 & {x}^{54} & {x}^{27} & 0 & 0 \\ 0 & 0 & 0 & 1 & {x}^{54} & {x}^{27} & 0 \\ 0 & 0 & 0 & 0 & 1 & {x}^{54} & {x}^{27}\end{matrix} ) ,$$

$$B = ( 1 + x + {x}^{6} ) {I}_{7} .$$

Each entry of the A circulant matrix corresponded to a 63×63 matrix (I=63), with entry 0 representing the all-zero matrix, entry 1 corresponding to the identity matrix and entries x²⁷ and x⁵⁴ being the shifted versions (by 27 and 54) of the identity matrix. For the B circulant matrix, each entry also corresponded to a 63×63 matrix which was repeated seven times across the diagonal of B (I₇ corresponds to the 7×7 identity matrix). For the H_{Z} matrix, each entry of both A and B matrices was transposed. The code was regular, with dᵥ=3 and d_{c}=6. The H_{X} and H_{Z} matrices of the code were given as: H_{X}=[A, B] and H_{Z}=[B^{T}, A^{T}]. Without loss of generality, since only X errors were considered, the focus was on the H_{Z} matrix of the code.

The 6-cycles of the B1 code were considered. Interestingly, all 6-cycles were only formed between variable nodes that belonged to the same circulant matrix. There were no 6-cycles formed between variable nodes that belonged to both circulant matrices. The trapping which corresponds to a 6-cycle is the (3, 3) one that is shown in FIG. 1A.

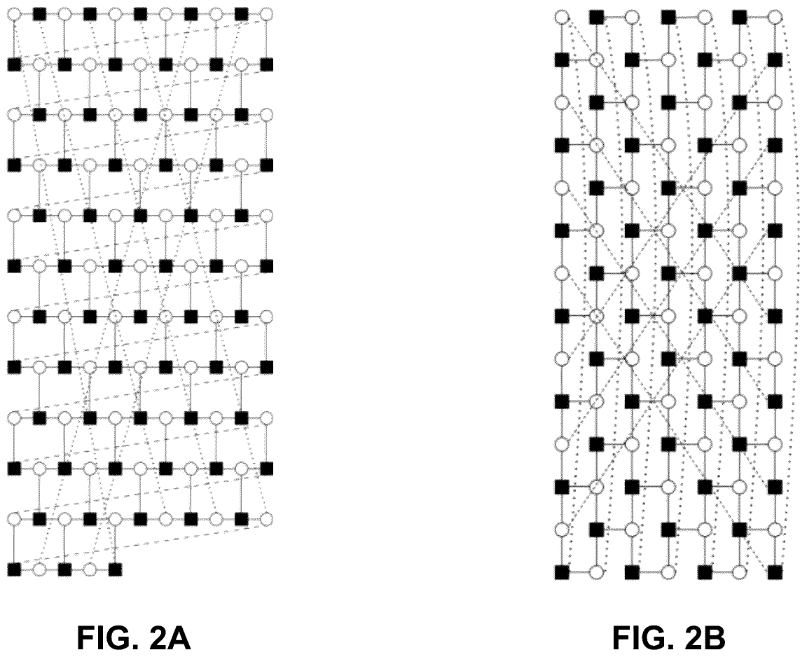

The (3, 3) trapping set inside the B^{T} matrix were considered. By searching for children trapping sets, the configurations were shown in FIGS. 1B-1D, which corresponded to interconnected 6-cycles. By enumerating the children of the 6-cycle, the trapping set depicted in FIG. 2A is achieved, which is a (63, 63) trapping set. This configuration corresponded to each 63×63 entry of the diagonal of the B^{T} matrix. The B^{T} matrix consisted of seven (63, 63) trapping sets which were independent with respect to B^{T}, meaning that the checks of each (63, 63) trapping set were not connected to variable nodes that belonged to other (63, 63) trapping sets.

A 6-cycle of the A^{T} matrix was obtained, which was also the parent to trapping sets formed by juxtaposing 6-cycles. By searching for children trapping sets, the (49, 49) trapping set was generated, shown in FIG. 2B. The A^{T} circulant matrix was therefore comprised of nine (49, 49) trapping sets which were not interconnected with each other and were only connected with the (63, 63) trapping sets of the other circulant matrix. The search stopped here since the (49, 49) and (63, 63) trapping sets also constituted stopping sets, which were directly connected to pseudocodewords and were harmful when decoded over the BSC. Pseudocodewords were considered to be attractor points of iterative message passing decoders, analogous to codewords, thereby determining the performance of iterative decoding.

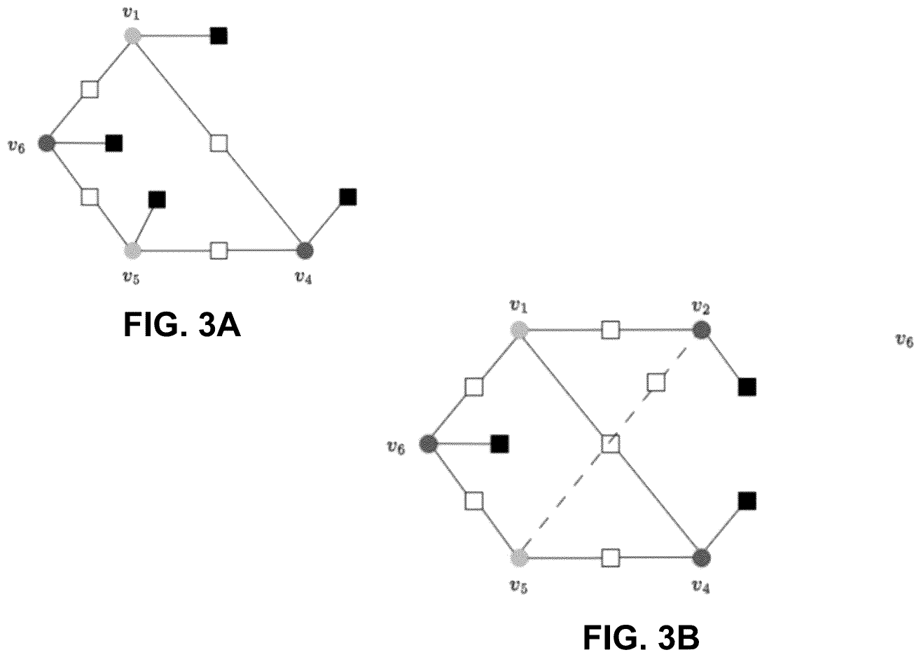

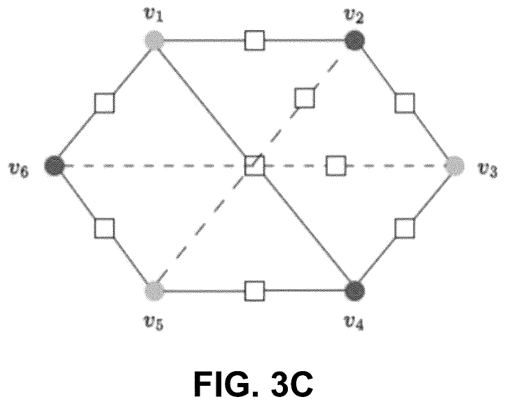

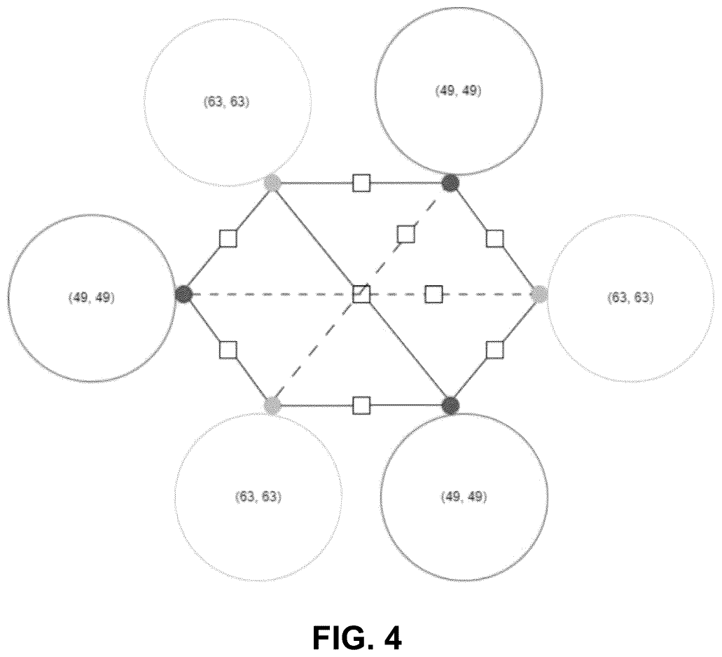

It was observed that 8-cycles were only formed between sets of variable nodes that belonged to both circulant matrices, and there was no 8-cycle inside each circulant matrix independently. The trapping set corresponding to an 8-cycle was the (4,4) one which is shown in FIG. 3A. Light-colored circles correspond to variable nodes of the B^{T} circulant matrix, and dark-colored variable nodes correspond to variable nodes of the A^{T} circulant matrix. Now, the degree-1 check nodes were connected by adding one variable node. Apparently, as illustrated in FIG. 3A, the degree-1 checks connected to light-colored variable nodes, shared a neighboring variable node, thus forming the (5, 3) trapping set (FIG. 3B). Finally, all the dangling degree-1 checks were connected when one more node was added to the (5, 3) trapping set. This led to the generation of the (6, 0) trapping set, which was a symmetric stabilizer and is illustrated in FIG. 3C. The (6, 0) trapping set consisted of nine interconnected 8-cycles formed between the two circulant matrices. Each variable node was contained in three (6, 0) trapping sets and 18 8-cycles. Every 8-cycle of the code led to the formation of the (6, 0) quantum trapping set. The set of six variable nodes inside the (6, 0) trapping set corresponded to the support of a check of the H_{X} matrix. Also, FIG. 4 shows that the (6, 0) trapping sets interconnected the (63, 63) and (49, 49) classical trapping sets.

Beyond the B1 code, it was shown that similar classical trapping sets, such as the (49, 49) and (63, 63) were also found in other degree-3 codes like GHP, HP, and bicycle codes. These codes exhibited a 2D grid-like structure composed of 6-cycles. For instance, it was found that it contained five (127, 127) trapping sets. These configurations shared a similar grid-like structure to the (63, 63) trapping set, except that each row of the grid contained six interconnected 6-cycles. Similarly, the HP code contained the (31, 31) trapping set. These low variable degree codes were also known to perform poorly under iterative decoding as they also exhibited (6, 0) quantum trapping sets.

Finally, for every dᵥ-3, d_{c}-6 GHP code, since one of the circulant matrices was constructed by using a weight-3 polynomial, and provided that no 8-cycles lay inside the circulant, then the trapping sets of that circulant matrix was a grid-like structure of 6-cycles. In such case, the (6, 0) trapping set was present. Hence, it was crucial to devise a decoding framework that was able to correct error patterns appearing in such configurations.

The trapping set analysis of the B1 code indicated that the BF decoder was expected to exhibit poor performance for dᵥ-3 GHP codes, despite being a good candidate for low-latency applications. In particular, it was proven that for dᵥ₋₃ variable-regular codes, the guaranteed error correction capability of the BF algorithm was upper bounded by [g/4]-1. Therefore, the fact that a dᵥ₋₃ code with g=6 or g=8 could not correct certain weight two error patterns made the algorithm impractical. Also, the girth of QLDPC codes was usually small, and in the case of HP and GHP codes, it could not be higher than eight. Hence, bit-flipping-based decoders were utilized with better error correction capabilities, accompanied by higher granularity, and allowing collective decoding.

The quantum equivalent of the classical TBF was presented. In contrast to the BF decoder, which assigned two possible states to each variable and check node (one-bit precision), TBF used two-bit precision, allowing more states to describe both variable and check nodes. For the check nodes, an additional bit was used to describe the value of the check in the previous iteration. A satisfied (unsatisfied) check node c was called previously satisfied (previously unsatisfied) if it was satisfied (unsatisfied) in the previous decoding iteration and it was still satisfied (unsatisfied) in the current iteration, which means that its residual syndrome r_{c}=0 (or r_{c}=1) for both iterations. In the other case, the check node was called newly satisfied (newly unsatisfied), which means that the residual syndrome r_{c} flips in the current iteration. The states of a previously satisfied, a newly satisfied, a previously unsatisfied, and a newly unsatisfied check node were denoted as 0_{old}, 0_{new}, 1_{old}, and 1_{new}, respectively.

Let

$${z}^{l} = ( {z}_{1}^{l} , {z}_{2}^{l} , … , {z}_{m}^{l} )$$

be a vector such that

$${z}_{c}^{l} ∈ \{ {0}_{old} , {0}_{new} , {1}_{o l d} , {1}_{new} \}$$

gives the state of check node c at the end of the I^{th} iteration. The check node update function Φ was defined as follows:

$${z}_{c}^{ℓ} ← Φ ( {r}_{c}^{ℓ − 1} , {r}_{c}^{ℓ} ) = \{ \begin{matrix}{0}_{old} , & if ( {r}_{c}^{ℓ − 1} , {r}_{c}^{ℓ} ) = ( 0 , 0 ) \\ {1}_{new} , & if ( {r}_{c}^{ℓ − 1} , {r}_{c}^{ℓ} ) = ( 0 , 1 ) \\ {0}_{new} , & if ( {r}_{c}^{ℓ − 1} , {r}_{c}^{ℓ} ) = ( 1 , 0 ) \\ {1}_{old ,} & if ( {r}_{c}^{ℓ − 1} , {r}_{c}^{ℓ} ) = ( 1 , 1 )\end{matrix} .$$

The initial states of check nodes are computed at iteration I=0 based on the received syndrome s, as follows:

$${z}_{c}^{0} ← {Δ}_{c} ( {s}_{c} ) ∈ \{ \begin{matrix}\{ {0}_{old} , {0}_{new} \} , & if {s}_{c} = 0 \\ \{ {1}_{old} , {1}_{new} \} , & if {s}_{c} = 1\end{matrix} .$$

Hence, if the received syndrome of a check equals zero, the check was initialized either as previously satisfied or as newly satisfied. On the other hand, if the received syndrome of a check equals one, the check was initialized either as previously unsatisfied or as newly unsatisfied. This was an indication of the granularity offered by TBF decoding, which was exploited via collective decoding.

In the case of variable nodes, the additional bit was used to represent their “strength”. A variable node v was classified as either a “strong” variable node or a “weak” variable node. The intuition behind this classification was that variable nodes were treated differently with respect to their strength. For example, a variable node that was marked as weak was flipped more easily than a variable node marked as strong in the subsequent iteration. Therefore, v was described by four states instead of two, which were the following: 00, 01, 10, 11, where the most significant bit (MSB) denoted the value of v and the least significant bit (LSB) denoted the strength of v.

Let

$${w}^{l} = ( {w}_{1}^{l} , {w}_{2}^{l} , … , {w}_{n}^{l} ) ,$$

such that

$${w}_{v}^{l} ∈ \{ 00 , 01 , 10 , 11 \}$$

gives the state of variable node v at the end of the I^{th} iteration. The hard decision of v at the I^{th} iteration was extracted using the MSB as:

$$M S B ( {w}_{v}^{l} )$$

and the error estimate vector ê^{l} corresponded to the hard decision part of w^{l}.

States of variable nodes were initialized to Δv∈{00, 01} since no channel values were received. The variable node update function was used to compute the updated variable node state and was defined by:

$${w}_{v}^{ℓ + 1} = \{ \begin{matrix}{w}_{v}^{ℓ} , & if {𝒳}^{ℓ} ( v ) = ( 2 , 0 , 0 ) \\ 00 , & if {𝒳}^{ℓ} ( v ) = ( 1 , 0 , 1 ) \& {w}_{v}^{ℓ} ∈ ( 01 , 00 ) \\ 10 , & if {𝒳}^{ℓ} ( v ) = ( 1 , 0 , 1 ) \& {w}_{v}^{ℓ} ∈ ( 10 , 11 ) \\ Ψ ( {w}_{v}^{ℓ} , {𝒳}_{1}^{ℓ} ( v ) ) , & otherwise\end{matrix} . \qquad ( 5 )$$

Here,

$${X}^{I} ( v ) = ( {X}_{{0}_{old}}^{l} ( v ) , {X}_{{0}_{new}}^{l} ( v ) , {X}_{{1}_{old}}^{l} ( v ) )$$

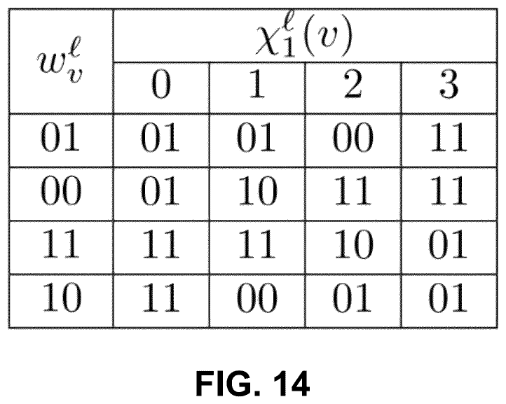

denotes the 3-tuple containing the number of previously satisfied, newly satisfied, and previously unsatisfied neighboring check nodes of v respectively, and the function Ψ is described in FIG. 14. The function Ψ computed the next state of each variable node by using the number of its adjacent unsatisfied checks

$${X}_{1}^{l} ( v )$$

and its current state

$${w}_{v}^{l} .$$

In FIG. 14., for the case of three unsatisfied checks both weak and strong bits were flipped to strong bits. In the case of two unsatisfied checks, strong bits became weak and, in turn, weak bits were flipped to strong bits. Finally, for one unsatisfied check, weak bits were flipped to weak bits, whereas for no unsatisfied checks, bits became strong while retaining their hard decision value. Note that Ψ defined (5) for any input configuration except the following two cases. Firstly, when a variable node v was connected to two previously satisfied checks, zero newly satisfied checks, and zero previously unsatisfied check nodes—i.e., X^{l}(v)=(2, 0, 0), then the state of v was not modified. Secondly, when X^{l}(v)=(1, 0, 1), the decoding rule forced v to become weak, i.e., LSB was set to zero. All such subtleties were captured in the variable node update function in a TBF algorithm. (5) and Ψ function of FIG. 14 corresponded to a single example of a realization of a TBF decoder. More generally, the variable node update had many different realizations giving more flexibility in the decoding rule. Multiple realizations of (5) were used in order to develop the collective decoding framework.

The granularity offered by the variable node update function (5) helped to develop TBF decoders with diverse error-correction capabilities. Each TBF decoder was uniquely determined as: D=(Ψ, f), where f is a function that determines how the variable nodes are updated as described next. Variable node function Ψ was described as a look-up-table like the one shown in FIG. 14, and in general, it was applied to any subset of variable nodes. Multiple Ψ functions was deployed to cover the whole set of variable nodes V. In such case, a Ψ function corresponded to a subset Vᵢ⊆V will be denoted as Ψ^{Vi}. For the majority of decoders used in the simulations, Ψ was as described in FIG. 14. This was based on the observation that one should be cautious while relaxing the bit flipping criteria of the Ψ function, as logical errors can be introduced in cases where bits with small number of unsatisfied checks are simultaneously flipped. Consequently, most of the decoders were defined by modifying the f function, which made the bit flipping procedure more conservative.

f was defined to be a sequence of nine binary values (flags) that determined how (5) was applied to any subset Vᵢ⊆V of variable nodes, as: f^{Vi}=(IΔᵥ, IΔ_{c}, W₁₁₀, W₂₀₀, W₂₀₁, W₁₀₁, W₀₁₁, W₁₁₁, W₀₂₀) (Equation 6). The first two parameters acted on the initialization of variable and check nodes, i.e., Δᵥ and Δ_{c}, respectively. If IΔᵥ=1, then all variable nodes were initialized as Δᵥ=00 (weak zero), otherwise, they were initialized as Δᵥ=01 (strong zero). If IΔ_{c}=1, then check nodes were initialized as Δ_{c}(S_{c})∈{0_{new}, 1_{new}} (newly satisfied/unsatisfied), depending on their binary value, s_{c}. If IΔ_{c}=0, check nodes were initialized as Δ_{c}(s_{c})∈{0_{old}, 1_{old}} (previously satisfied/unsatisfied) depending on their binary value, s_{c}. For the rest of the parameters, the subscript 3-tuple corresponded to X^{I}(v), where v∈Vᵢ.

If W₁₀₁=1, then the state of a variable node v connected to one previously satisfied, zero newly satisfied, and one previously unsatisfied check remained the same for that iteration, thus:

$${w}_{v}^{ℓ + 1} = \{ \begin{matrix}{w}_{v}^{ℓ} , & if ( {W}_{101} = 1 \& * {\text{?}}_{101} ( {𝒳}^{ℓ} ( v ) ) = 1 ) \\ Ψ ( {w}_{v}^{ℓ} , {𝒳}_{1}^{ℓ} ( v ) ) , & if ( {W}_{101} = 0 \& {\text{?}}_{101} ( {𝒳}^{ℓ} ( v ) ) = 1 )\end{matrix} . \qquad ( 7 )$$

$$Where ,$$

$${\text{?}}_{101} ( {𝒳}^{ℓ} ( v ) ) = \{ \begin{matrix}1 , & if {𝒳}^{ℓ} ( v ) = ( 1 , 0 , 1 ) \\ 0 , & otherwise\end{matrix} , \qquad ( 8 )$$

is the indicator function. The remaining parameters were also described using equations similar to (7). If W₂₀₀=1, then the state of a variable node connected to two previously satisfied, zero newly satisfied, and zero previously unsatisfied check becomes weak, otherwise, if W₂₀₀=0, the state of the particular variable node remains the same for that iteration. This was described by the following equation:

$${w}_{v}^{ℓ + 1} = \{ \begin{matrix}00 , & if ( {W}_{200} = 1 \& {\text{?}}_{200} ( {𝒳}^{ℓ} ( v ) ) = 1 ) \& {w}_{v}^{ℓ} ∈ ( 01 , 00 ) \\ 10 , & if ( {W}_{200} = 1 \& {\text{?}}_{200} ( {𝒳}^{ℓ} ( v ) ) = 1 ) \& {w}_{v}^{ℓ} ∈ ( 10 , 11 ) \\ {w}_{v}^{ℓ} , & if ( {W}_{200} = 0 \& {\text{?}}_{200} ( {𝒳}^{ℓ} ( v ) ) = 1 )\end{matrix} . \qquad ( 9 )$$

The same rule applied for W₁₁₀. Finally, if W₂₀₁=1, then the state of a variable node connected to two previously satisfied, zero newly satisfied, and one previously unsatisfied checks became weak. This was described by the following equation:

$${w}_{v}^{ℓ + 1} = \{ \begin{matrix}00 , & if ( {W}_{201} = 1 \& {\text{?}}_{201} ( {𝒳}^{ℓ} ( v ) ) = 1 ) \& {w}_{v}^{ℓ} ∈ ( 01 , 00 ) \\ 10 , & if ( {W}_{201} = 1 \& {\text{?}}_{201} ( {𝒳}^{ℓ} ( v ) ) = 1 ) \& {w}_{v}^{ℓ} ∈ ( 10 , 11 ) \\ Ψ ( {w}_{v}^{ℓ} , {𝒳}_{1}^{ℓ} ( v ) ) , & if ( {W}_{201} = 0 \& {\text{?}}_{201} ( {𝒳}^{ℓ} ( v ) ) = 1 )\end{matrix} . \qquad ( 10 )$$

The rest of the parameters have the same behavior as W₂₀₁.

The collective decoding framework was denoted by D_{N}_{_{D}}={Dᵢ|i=1, . . . , N_{D}}, which was the set of TBF decoders, where No was the cardinality of the set and Dᵢ=(Ψᵢ, fᵢ) describes each individual decoder of the set, which was uniquely defined. The set of N_{D} decoders was used in parallel so that it provided guaranteed correction within the allowed decoding time budget. Regarding the f function, although the number of all possible 3-tuples was more than nine, for the purposes of our decoding analysis and in order to limit the complexity, the aforementioned 9 bit-values were chosen. The total number of decoders was 2⁹-512 and was denoted by Dₜₒₜ. These nine parameters were selected through empirical analysis of low-weight error patterns, as illustrated in the following example.

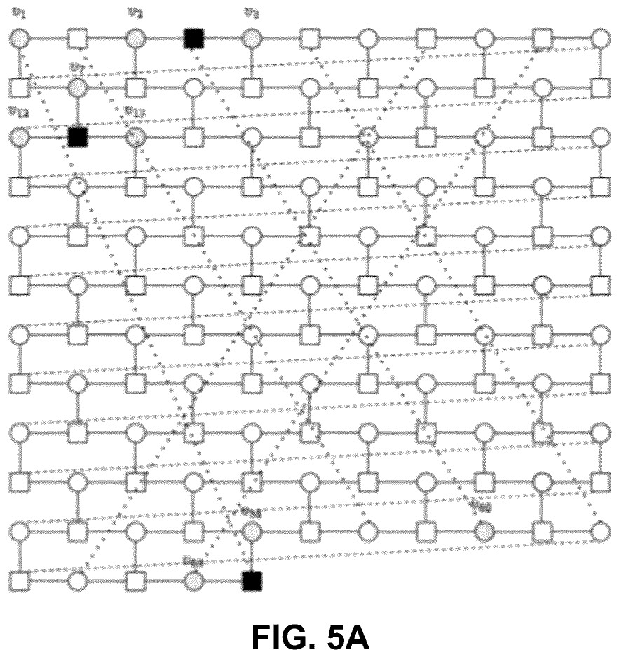

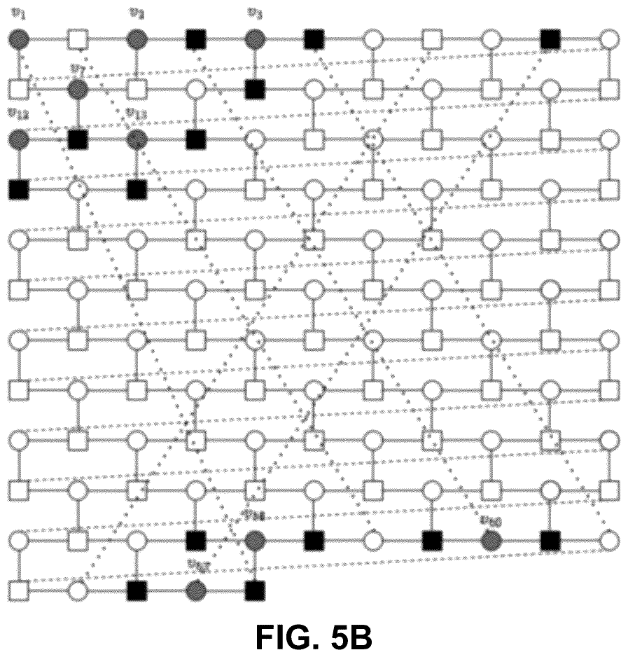

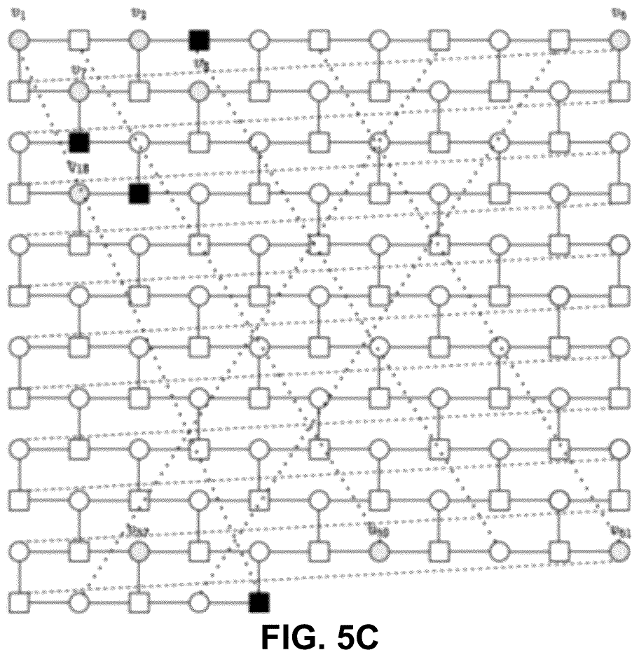

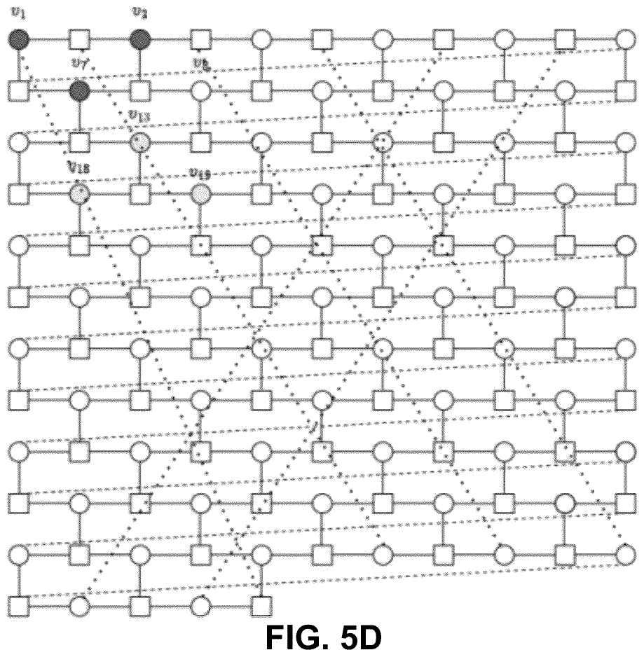

Consider a TBF decoder based on FIG. 14, with all variable nodes initialized as strong zeros. Flags W₂₀₁ and W₁₁₁ assisted in correcting errors in (3, 3) trapping sets, as in FIG. 5. Without these flags, each variable node required at least two unsatisfied checks to change state, causing convergence to fail. With W₂₀₁ and W₁₁₁ enabled, no bits flip in the first iteration as each variable node has only one unsatisfied check. In the second iteration, bits in the three residual checks' support were marked “weak” due to two previously satisfied and one unsatisfied check. During the third iteration, bits previously marked as weak flipped, while bits connected to three unsatisfied checks turned strong, and others reverted to weak. Variable nodes v₁, v₂, and v₇, with only one unsatisfied check, flipped in the next iteration, while v₁₈ remained unchanged due to W₁₁₁. This process ensured convergence within four iterations by limiting flips and preventing logical errors. The rest of the parameters were selected in a similar manner, by examining weight-4 and weight-5 harmful error-patterns.

The goal was to correct all error patterns that appeared inside the (6, 0) trapping set and all error patterns up to weight-t inside the (49, 49) and (63, 63) trapping sets, where t was a chosen parameter. Since those configurations were replicated multiple times, the error-floor performance was improved. The BF algorithm was a starting point of the analysis. BF was a special case of a TBF decoder.

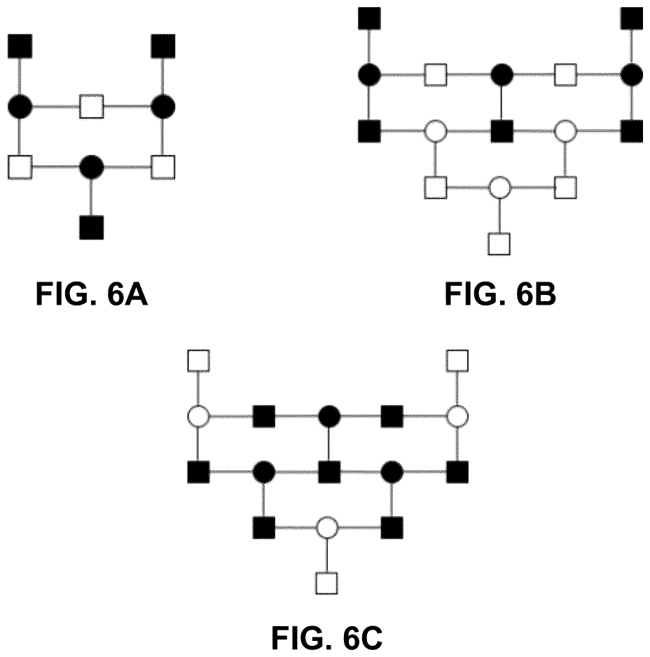

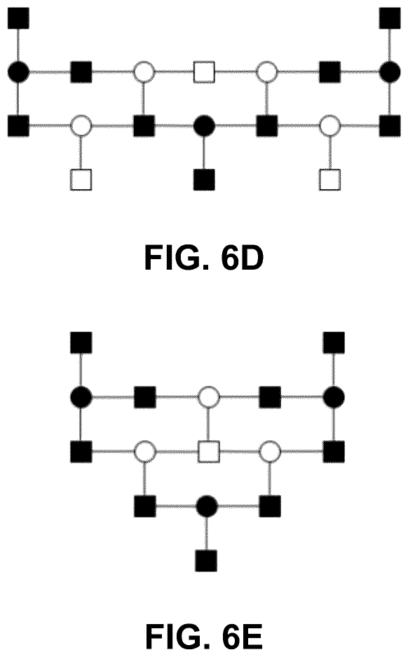

Since both (49, 49) and (63, 63) trapping sets were formed by grid-like structures of 6-cycles, the following analysis applied to both of them. BF flipped every bit that had two or more unsatisfied checks in their neighborhood. BF corrected every weight-1 and weight-2 error pattern that appeared in both (49, 49) and (63, 63) trapping sets. BF cannot correct the types of weight-3 error patterns that are depicted in FIGS. 6A-6E. The weight-3 error patterns appear inside the (3, 3) trapping set (FIG. 6A) constituted fixed sets for BF decoder, so the decoder failed to correct them because the number of unsatisfied checks of all bits equaled one, therefore no variable node was flipped. Regarding the error patterns shown in FIGS. 6B-6E, BF exhibited oscillating behavior as it did not provide different treatment for variable nodes with two unsatisfied checks and variable nodes with three unsatisfied checks. All these error patterns were corrected by using the following TBF-based decoder which was more cautious while flipping bits: D₁=(Ψ₁, (0, 1, 0, 0, 1, 1, 0, 1, 0)), where Ψ₁ is given by FIG. 14. D₁ corrected the error patterns of FIGS. 6A-6E in five, four, one, one, and one iterations, respectively.

Regarding weight-4 error patterns, the D₁ decoder was used as a basis. The goal now was to first generate all possible weight-4 error patterns that appeared in the (49, 49) trapping set. For every weight-4 error pattern for which D₁ failed, the remaining 511 decoders, Dₜₒₜ\ {D₁} were run. Eventually, a decoder of that set was picked which was able to correct the largest number of weight-4 error patterns for which D₁ failed. It turned out that D₂=(Ψ₂, (0, 0, 0, 0, 0, 0, 0, 0, 0)), where Ψ₂ was given by FIG. 14, was able to correct every single one of those error patterns. Now that all weight-4 error patterns inside the (49, 49) trapping set were corrected, both D₁ and D₂ decoders were used as the basis for testing the correction of all weight-4 error patterns appearing in the (69, 69) trapping set. Following the same approach as before, it was found that decoder D₃=(Ψ₃, (0, 0, 0, 1, 0, 0, 0, 0, 0)), where Ψ₃ is given by FIG. 14, complemented D₁ and D₂ decoders in correcting all possible weight-4 error patterns appearing in both (49, 49) and (63, 63) trapping sets.

Finally, a recursive approach was outlined that generated a set of TBF-based decoders that collectively corrected all error patterns up to a certain weight, which appeared inside classical trapping sets. Eⁱ denotes the set of all error patterns of weight-j that are found inside the trapping set, while t denotes the desired error correction capability inside the trapping set. The aim was to correct all error patterns up to weight-t in the trapping set). Also,

$${E}_{D}^{j} ,$$

denotes the set of error patterns of weight-j that were correctable by the decoder D. All decoders of the set Dₜₒₜ were able to correct all weight-1 error patterns, so the algorithm began by initializing the set of available decoders as the D₁ decoder. Then, for all error patterns of weight-2, the rest of all possible 511 decoders of the set, Dₜₒₜ\{D₁}, were simulated and the one with the lowest frame error rate (FER), D, was added to the set D. The error patterns that were correctable by D were removed from the set Eⁱ. The process continued until either all error patterns of weight j were corrected or all the decoders of the set Dₜₒₜ\{D₁} were used. After all error patterns of a certain weight were corrected, the weight was incremented and the process continued. Eventually, this approach outputted the set of decoders D that corrected up to weight-(j-1) error patterns appearing inside a trapping set.

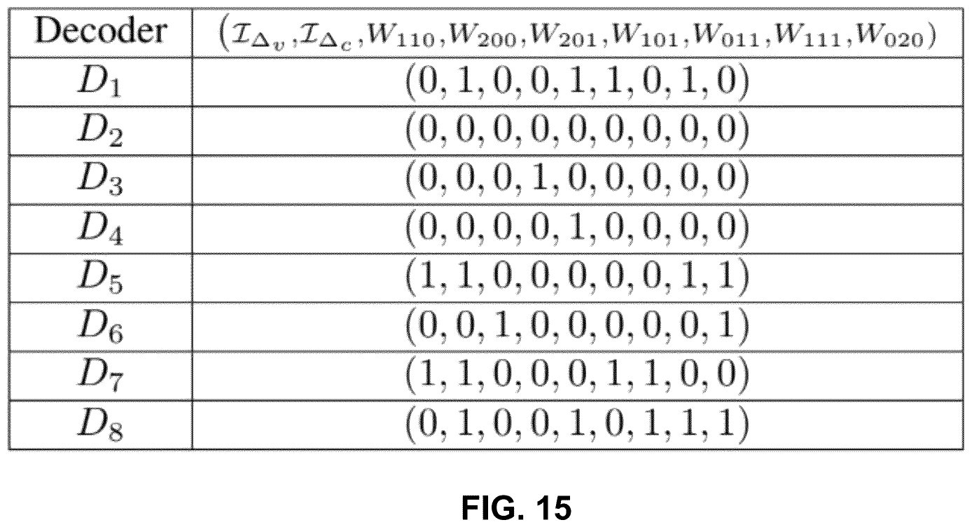

Finally, for each weight-j error pattern, the decoders needed to correct errors in the (49, 49) trapping set were first generated. This set of decoders was then used as the initial decoding set for handling similar patterns in the (63, 63) trapping set, as their structural similarities allowed mutual error correction. In FIG. 15, a set of eight TBF decoders is listed that guarantees the correction of all error patterns up to weight-5 that appear inside the (49, 49) and (63, 63) trapping sets.

The plain BF algorithm is considered. It was easy to see that all weight-1 error patterns appearing inside the (6, 0) trapping set could be corrected by BF. However, when it came to the weight-2 error patterns, BF could correct all of them except the ones that appear in diagonal positions of each 8-cycle, or (4, 4) trapping set. In that case, based on the decoding rule, BF kept flipping all four nodes back and forth without treating the variable nodes with two or three unsatisfied checks. Hence, there were two weight-2 error-patterns per (4, 4) trapping set that resulted in failure inducing sets. This problem was solved by using a less “aggressive” BF algorithm that introduced more granularity, such as D₁. By observing the parameters of D₁, it was clear that it would immediately flip all variable nodes with three unsatisfied checks while it would flag the variable nodes with two unsatisfied checks as “weak”, so it would be able to correct such error configurations in one iteration.

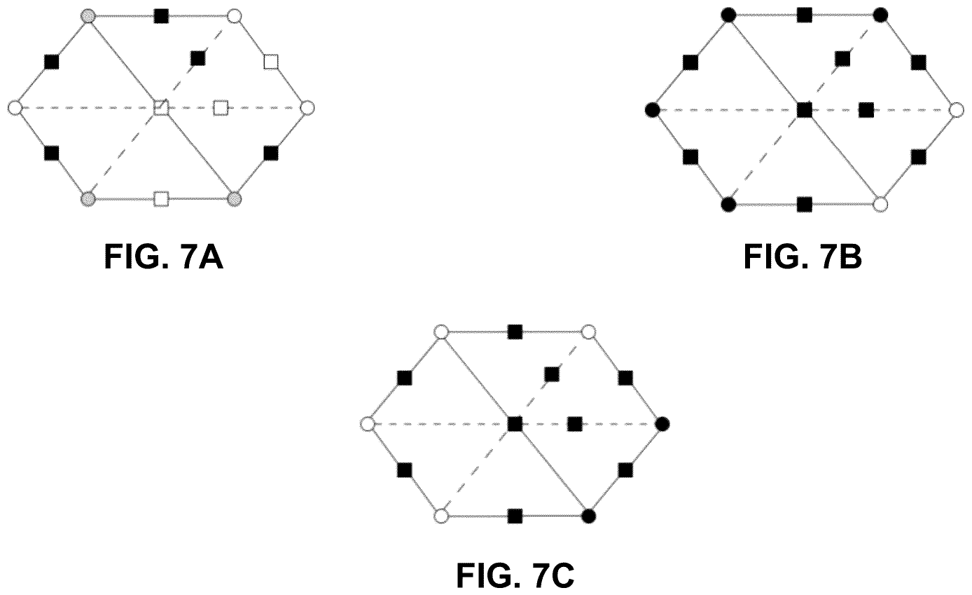

The analysis was continued by considering weight-3 error patterns, all of which were uncorrectable by D₁ due to the symmetry of the (6, 0) trapping set. Since (6, 0) trapping sets were only formed between the two circulant matrices, a TBF decoder was deployed that assigned different rules to variable nodes regarding which circulant matrix they belong to. For example, variable nodes with three unsatisfied checks in one circulant were immediately flipped, while variable nodes with three unsatisfied checks in the other circulant only got their energy reduced (become “weak”) so they could potentially be flipped in subsequent iterations. This action introduced asymmetry and the overall decoder introduced a “timing offset” to the variable nodes of one circulant matrix. An example of a weight-3 error configuration that could not be corrected by either BF or D1 is shown in FIG. 7. Such an error configuration could be corrected by employing different rules in each circulant matrix.

In conclusion, regarding the case of quantum trapping sets, a single TBF algorithm was developed that was more conservative in flipping the variable nodes of one circulant matrix and more aggressive with the variable nodes of the other circulant matrix. This approach enabled the algorithm to handle all possible error patterns in the (6, 0) trapping set. That algorithm is denoted as

$${D}_{9} = ( \{ {ψ}_{9}^{{V}_{1}} , {ψ}_{9}^{{V}_{2}} \} , ( 0 , 1 , 0 , 0 , 1 , 1 , 0 , 1 , 0 ) ) , where$$

$${ψ}_{9}^{{V}_{1}}$$

is described by FIG. 14,

$${ψ}_{9}^{{V}_{2}}$$

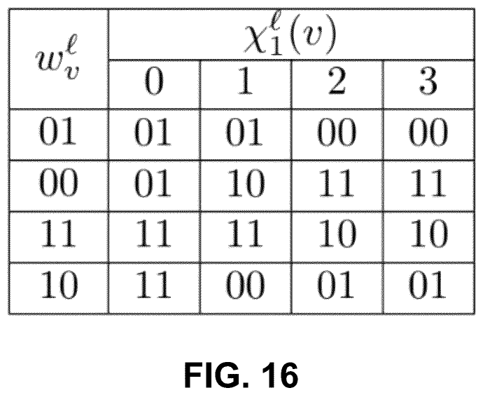

is described by FIG. 16, V₁={v₁, v₂, . . . , v_{n/2}} and V2={v_{n/2+1}, v_{n/2+2}, . . . , vₙ}. Due to its inherent asymmetry, D₉ corrected every error pattern inside the (6, 0) trapping set. Finally, from this analysis it was clear that the set D₉={D₁, D₂, D₃, D₄, D₅, D₆, D₇, D₈, D₉} was able to correct any error pattern up to weight-5 appearing inside the (49, 49) and (63, 63) classical trapping sets and any error pattern appearing inside a (6, 0) quantum trapping set.

The code was composed of nine (49, 49) trapping sets and seven (63, 63) trapping sets which were connected via symmetric stabilizers. Higher-weight error patterns were corrected by assigning different decoding rules to variable nodes depending on which circulant matrix they belong to. The type of error patterns aimed to correct were composed of up to weight-5 error-patterns appearing inside classical trapping sets of one circulant matrix and error patterns appearing inside a symmetric stabilizer (quantum trapping set). For example, it was observed that D₁ and D₉ are comprised of exactly the same function f with the difference that D₉ assigned a different Ψ function to the variable nodes of the second circulant matrix. This means that the set {D₁, D₉} aimed to correct all error patterns up to weight-3, which appeared inside any of the classical trapping sets of the first circulant matrix plus error patterns appearing inside (6, 0) trapping sets. In a similar manner, a new decoder was defined

$${D}_{10} = ( \{ {ψ}_{10}^{{V}_{1}} , {ψ}_{10}^{{V}_{2}} \} , ( 0 , 1 , 0 , 0 , 1 , 1 , 0 , 1 , 0 ) ) ,$$

$$where {ψ}_{10}^{{V}_{1}}$$

is described by FIG. 16 and

$${ψ}_{10}^{{V}_{2}}$$

is described by FIG. 14.

Hence, the sets {D₁, D₉} and {D₁₀, D₁} were employed to correct all classical weight-3 errors and errors inside symmetric stabilizers. Extending this idea, sets of decoders were built based on FIG. 15 wherein each of the decoders were complemented with two additional decoders with the corresponding f function and two differing 4 functions as for D₉ and D₁₀. This gave a set of 24 decoders that corrected error patterns up to weight-5 that appear inside classical trapping sets—(49,49) and (63,63), and all error patterns inside quantum trapping sets—(6,0). This set of 24 decoders helped improve both the waterfall and error-floor performance over the previous set of decoders for three different degree-3 QLDPC codes. In a similar manner, a set of decoders was developed that applied different rules to each of the 16 classical trapping sets of the code.

In terms of generalizing the decoder, a set of decoders capable of correcting error patterns within grids of interconnected 6-cycles of arbitrary sizes achieved strong error-floor performance across various QLDPC codes with variable degree-3. The decoding performance of the proposed decoders was simulated. Unless noted otherwise, the maximum number of iterations was set to 50. MS decoding was implemented for its better performance over BP when using a normalizing parameter. All decoders in the plots use parallel scheduling unless otherwise specified (e.g., layered decoding). Also, the set of decoders was run sequentially, as they were generated sequentially.

To illustrate the efficiency of the framework, some plots included bounded distance decoding (BDD) performance. The BDD formula is

$$B D D ( n , p ) = 1 - {\sum }_{j = 0}^{t} ( \begin{matrix}n \\ j\end{matrix} ) {{p}^{j} ( 1 - p )}^{n - j} ,$$

where t is the error correction capability. For smaller block lengths, BDD were applied directly to ensure numerical stability, though for larger n and t, numerical instability arose due to large binomial coefficients.

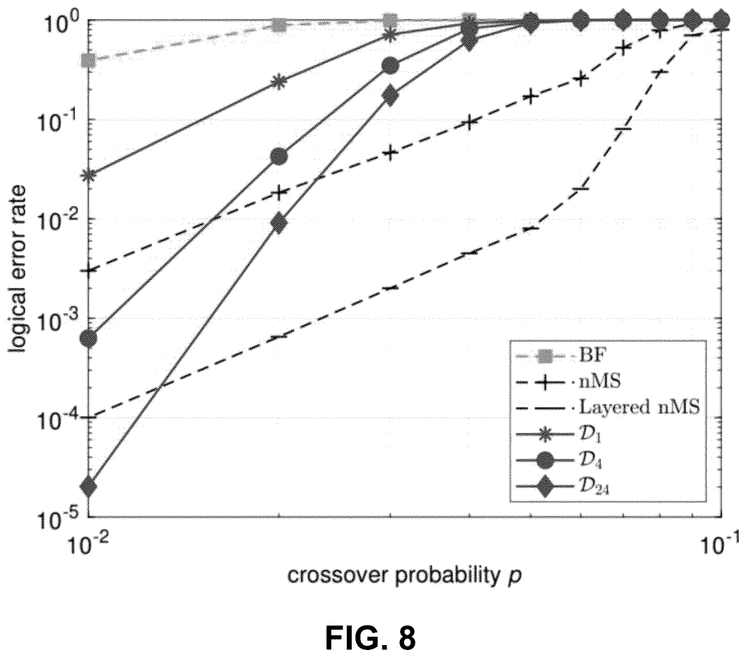

FIG. 8 illustrates the decoding performance of BF, normalized min-sum (nMS), layered nMS, and three sets of TBF decoders. The first set of TBF decoders consisted only of D₁=D₁ which corrected all error patterns up to weight-3 that appeared inside the (49, 49) and (63, 63) trapping sets. The second set of TBF decoders was comprised of D₄={D₁, D₂, D₃, D₉} which were given in FIG. 15 and corrected every weight-4 error pattern applied in either the (49, 49) trapping set or (63, 63) trapping set and every error pattern appearing in the (6, 0) trapping set independently. The poor performance of BF was attributed to its inability to correct error patterns of weight as low as two. On the other hand, it was observed that D₄ outperformed both BF and nMS, while D₂₄ also outperformed the layered nMS, which demonstrated an error-floor behavior.

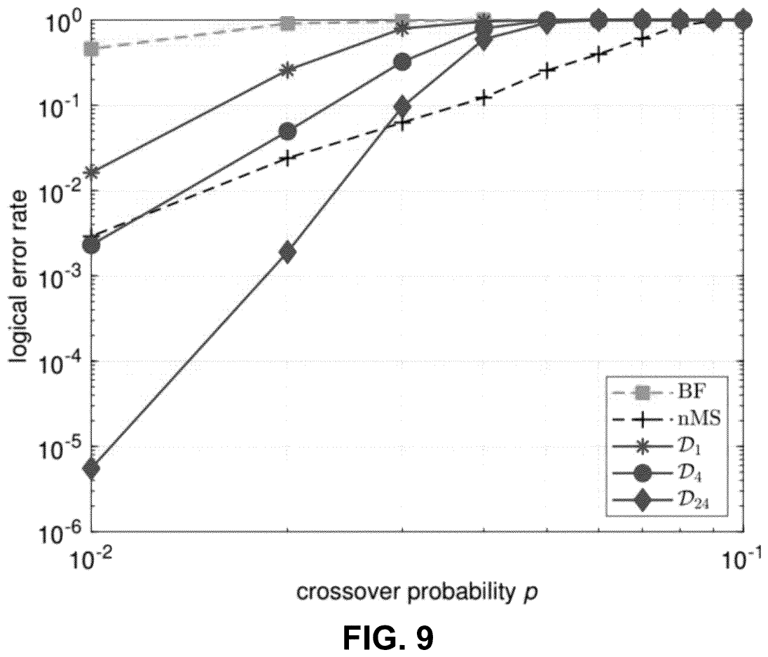

For the B3 code (FIG. 9), the performance of the ensembles of decoders is compared against the nMS algorithm. B3 code also contained the (6, 0) trapping sets, for which every error pattern that appears inside it was decoded. BF exhibited poor decoding performance, while the proposed set of four decoders (D₄) almost matched the performance of the nMS in the error-floor region. Interestingly, the performance gain of the ensemble of 24 decoders was higher for the B3 code when compared to the B1 code. This happened because the one circulant matrix of B3 was also composed of grid-like structure of 6-cycles, similar to the B1 code, but the other circulant matrix had a girth equal to 10, which further enhanced the performance of our scheme due to its sparsity.

In addition, the proposed ensemble of decoders for a family of dᵥ₋₃ QLDPC codes included the Bivariate Bicycle (BB) LDPC codes. BB codes were the first example of high-rate, large-distance QLDPC codes achieving the pseudo-threshold close to 1% under the circuit-based noise model. These codes shared a similar structure to the family of GHP that was studied, so it was expected that the proposed set of decoders would improve their performance as well.

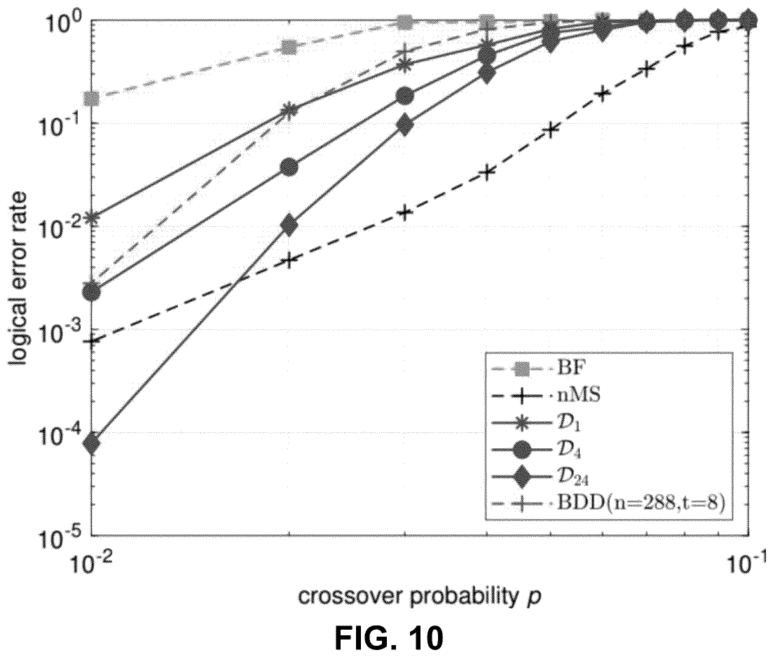

In FIG. 10, the performance of nMS is compared against that of D₁, D₄, and D₂₄. For the code, it was noticed that collective decoding still outperformed nMS, but the gain over the error correction performance was less than the one observed for the B1 and B3 codes. This happened because the code did not contain the (63, 63) and (49, 49) trapping sets. Nevertheless, since BB codes still contained the (6, 0) trapping sets and their classical trapping sets were formed by juxtaposing 6-cycles, D₂₄ performed about 10 times better than nMS for a crossover probability equal to 0.01. It was also noted that no error-floor behavior was observed for any of the three sets of decoders.

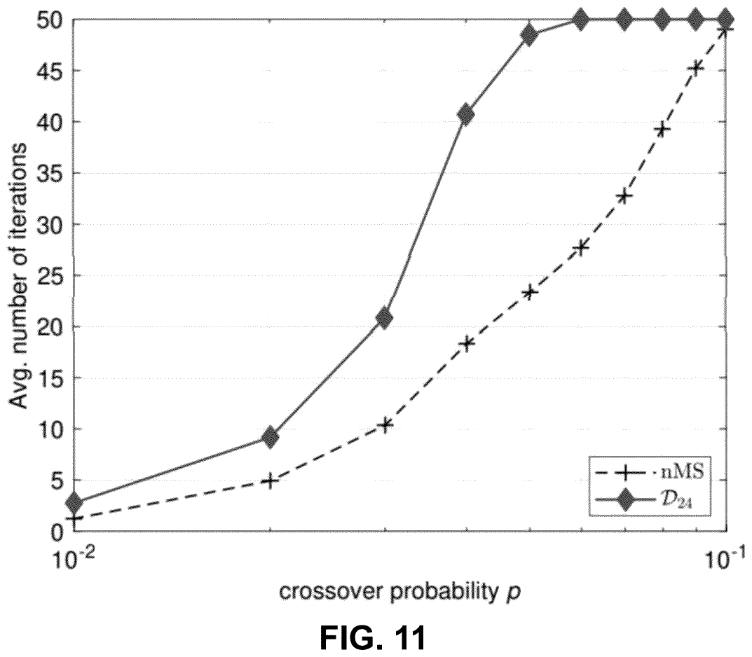

FIG. 11 demonstrates the average number of decoding iterations required by D₂₄ vs. the nMS decoder for the B3 code (corresponding to FIG. 9). It was observed that for a crossover probability of 0.01, D₂₄ attained about 1000 times better performance than nMS by only requiring about 2.5 iterations, while nMS required 1.2 iterations. A TBF-based decoding iteration was expected to require less latency than a nMS iteration; therefore, the collective decoding approach provided a good performance/latency trade-off.

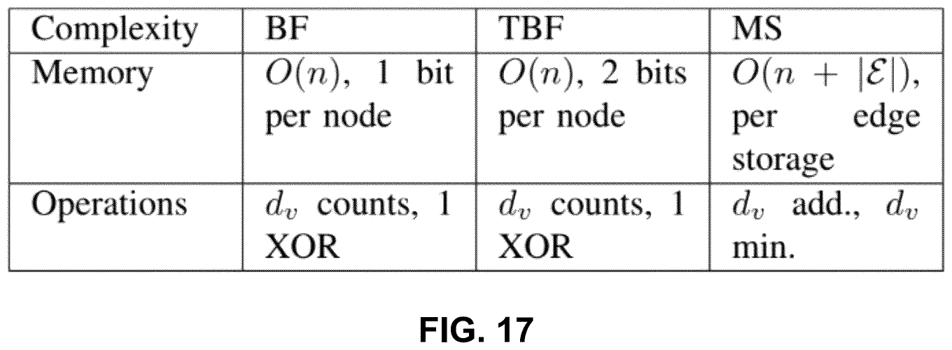

Finally, to evaluate per-iteration complexity, BF and TBF maintained O(n) complexity by processing each variable node independently with counting and XOR operations, however TBF added an extra bit for state tracking. TBF's memory overhead doubled to store this additional bit, but the asymptotic complexity remained linear. In comparison, MS decoding also has O(n) complexity but involves higher arithmetic complexity with dᵥ additions and minimum operations per variable node, making TBF more efficient in terms of operation simplicity. FIG. 17 summarizes the memory and operational complexity of BF, TBF, and MS decoders. Evidently, TBF decoder provided a good trade-off between performance and complexity.

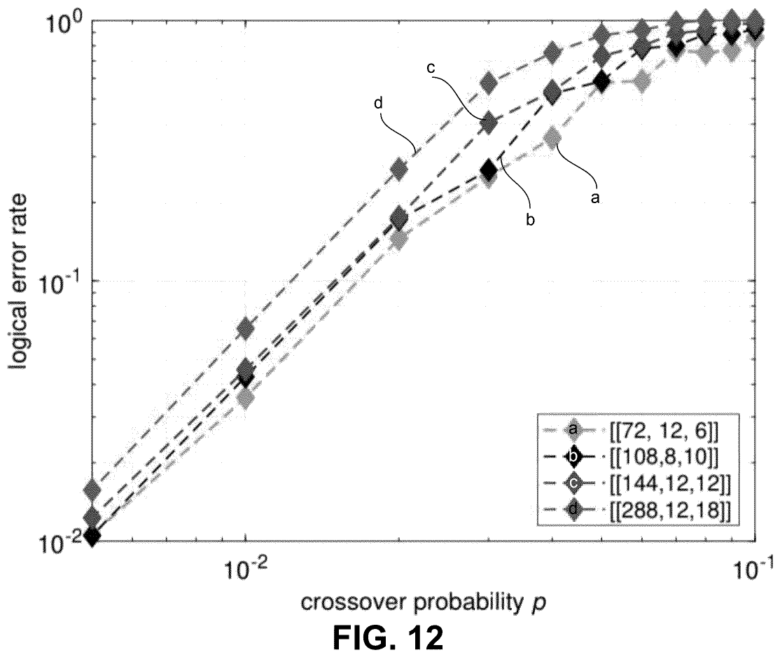

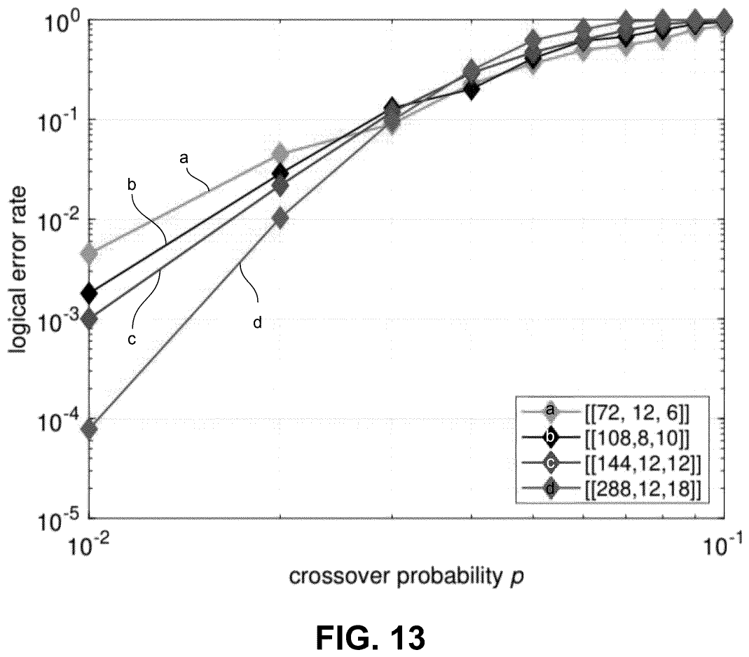

This framework was compared against SSF. The simulations revealed that SSF struggled for low-degree codes, such as BB codes, due to its inability to handle (3, 3) trapping sets. Specifically, SSF was limited by stopping syndromes, where there was no subset of generators in the X matrix capable of reducing the syndrome weight. This limitation existed because SSF required a monotonically decreasing syndrome weight, which prevented it from flipping bits in cases where an initial increase in syndrome weight was necessary for convergence (like in the example of FIGS. 5A-5D). FIG. 12 illustrates that SSF does not achieve a threshold for BB codes, with its performance degrading as block length increases. This decoding framework was able to achieve a threshold of approximately 3% for the same family of codes, as shown in FIG. 13.

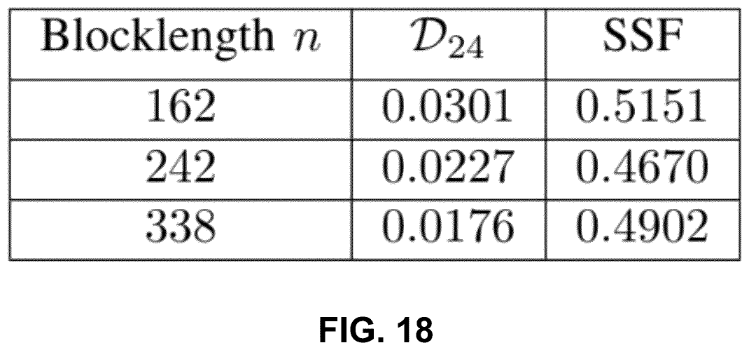

Finally, FIG. 18 provides a quantitative comparison of the decoder with SSF for randomly generated HP codes of dᵥ=3 and d_{c}=6. The random HP codes constructed were free of 4-cycles, and for the simulations, a BSC inducing X errors was assumed with a fixed crossover probability of p=0.01. The average logical error rate over 50 random codes was presented, demonstrating that the TBF framework improved its performance with increasing code length. The same table confirmed that (3, 3) trapping sets were detrimental for SSF.

In general, the arrangement of 6-cycles within the grid was important. Fewer TBF decoders were needed to correct errors within the (49, 49) trapping set than the (63, 63) set due to the sparser structure of the former, which had longer chains of interconnected 6-cycles. Addressing error patterns within trapping sets formed by interconnected 6-cycles was key for decoding dv-3, dc-6 QLDPC codes, as shown by the strong error-floor performance of the proposed ensembles.

A decoding method was presented that applied to families of QLDPC codes with specific characteristics and improved their error-floor performance under low-latency requirements. The proposed decoder was a product of the trapping set analysis of dᵥ-3 QLDPC codes and comprised multiple TBF decoders that run in parallel and collectively corrected error patterns appearing inside harmful configurations. Performance results demonstrated that this approach significantly outperformed MS, mainly in the error-floor region, and did so in fewer iterations (on average, two iterations for a crossover probability of 0.01), thus addressing the stringent latency requirements of quantum decoding.

The computer system can include a desktop computer, a workstation computer, a laptop computer, a netbook computer, a tablet, a handheld computer (including a smartphone), a server, a supercomputer, a wearable computer (including a SmartWatch™), or the like and can include digital electronic circuitry, firmware, hardware, memory, a computer storage medium, a computer program, a processor (including a programmed processor), an imaging apparatus, wired/wireless communication components, or the like. The computing system may include a desktop computer with a screen, a tower, and components to connect the two. The tower can store digital images, numerical data, text data, or any other kind of data in binary form, hexadecimal form, octal form, or any other data format in the memory component. The data/images can also be stored in a server communicatively coupled to the computer system. The images can also be divided into a matrix of pixels, known as a bitmap that indicates a color for each pixel along the horizontal axis and the vertical axis. The pixels can include a digital value of one or more bits, defined by the bit depth. Each pixel may comprise three values, each value corresponding to a major color component (red, green, and blue). A size of each pixel in data can range from a 8 bits to 24 bits. The network or a direct connection interconnects the imaging apparatus and the computer system.

The term “processor” encompasses all kinds of apparatus, devices, and machines for processing data, including by way of example a programmable microprocessor, a microcontroller comprising a microprocessor and a memory component, an embedded processor, a digital signal processor, a media processor, a computer, a system on a chip, or multiple ones, or combinations, of the foregoing. The apparatus can include special-purpose logic circuitry, e.g., an FPGA (field programmable gate array) or an ASIC (application-specific integrated circuit). Logic circuitry may comprise multiplexers, registers, arithmetic logic units (ALUs), computer memory, look-up tables, flip-flops (FF), wires, input blocks, output blocks, read-only memory, randomly accessible memory, electronically-erasable programmable read-only memory, flash memory, discrete gate or transistor logic, discrete hardware components, or any combination thereof. The apparatus also can include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures. The processor may include one or more processors of any type, such as central processing units (CPUs), graphics processing units (GPUs), special-purpose signal or image processors, field-programmable gate arrays (FPGAs), tensor processing units (TPUs), and so forth.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, subprograms, or portions of code). A computer program can be deployed to be executed on one computer or on multiple computers that are located at one site or distributed across multiple sites and interconnected by a communication network.

Embodiments of the subject matter and the operations described herein can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer programs, i.e., one or more modules of computer program instructions, encoded on computer storage medium for execution by, or to control the operation of, a data processing apparatus.

A computer storage medium can be, or can be included in, a computer-readable storage device, a computer-readable storage substrate, a random or serial access memory array or device, or a combination of one or more of them. Moreover, while a computer storage medium is not a propagated signal, a computer storage medium can be a source or destination of computer program instructions encoded in an artificially generated propagated signal. The computer storage medium can also be, or can be included in, one or more separate physical components or media (e.g., multiple CDs, drives, or other storage devices). The operations described in this specification can be implemented as operations performed by a data processing apparatus on data stored on one or more computer-readable storage devices or received from other sources.

Program code embodied on a computer readable medium may be transmitted using any appropriate medium, including but not limited to wireless, wireline, optical fiber cable, R.F, Bluetooth, storage media, computer buses, etc., or any suitable combination of the foregoing. Computer program code for carrying out operations for aspects of the present disclosure may be written in any combination of one or more programming languages, including an object oriented programming language such as Java, Smalltalk, C#, Ruby, or the like, conventional procedural programming languages, such as Pascal, FORTRAN, BASIC, or similar programming languages, programming languages that have both object-oriented and procedural aspects, such as the “C” programming language, C++, Python, or the like, conventional functional programming languages such as Scheme, Common Lisp, Elixir, or the like, conventional scripting programming languages such as PHP, Perl, Javascript, or the like, or conventional logic programming languages such as PROLOG, ASAP, Datalog, or the like.

The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks.

However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

Computers typically include known components, such as a processor, an operating system, system memory, memory storage devices, input-output controllers, input-output devices, and display devices. It will also be understood by those of ordinary skill in the relevant art that there are many possible configurations and components of a computer and may also include cache memory, a data backup unit, and many other devices. To provide for interaction with a user, embodiments of the subject matter described in this specification can be implemented on a computer having a display device, e.g., an LCD (liquid crystal display), LED (light emitting diode) display, or OLED (organic light emitting diode) display, for displaying information to the user.

Examples of input devices include a keyboard, cursor control devices (e.g., a mouse or a trackball), a microphone, a scanner, and so forth, wherein the user can provide input to the computer. Other kinds of devices can be used to provide for interaction with a user as well; for example, feedback provided to the user can be in any form of sensory feedback, e.g., visual feedback, auditory feedback, or tactile feedback; and input from the user can be received in any form, including acoustic, speech, or tactile input. Examples of output devices include a display device (e.g., a monitor or projector), speakers, a printer, a network card, and so forth. Display devices may include display devices that provide visual information, this information typically may be logically and/or physically organized as an array of pixels. In addition, a computer can interact with a user by sending documents to and receiving documents from a device that is used by the user; for example, by sending web pages to a web browser on a user's client device in response to requests received from the web browser.

An interface controller may also be included that may comprise any of a variety of known or future software programs for providing input and output interfaces. For example, interfaces may include what are generally referred to as “Graphical User Interfaces” (often referred to as GUI's) that provide one or more graphical representations to a user. Interfaces are typically enabled to accept user inputs using means of selection or input known to those of ordinary skill in the related art. In some implementations, the interface may be a touch screen that can be used to display information and receive input from a user. In the same or alternative embodiments, applications on a computer may employ an interface that includes what are referred to as “command line interfaces” (often referred to as CLI's). CLI's typically provide a text based interaction between an application and a user. Typically, command line interfaces present output and receive input as lines of text through display devices. For example, some implementations may include what are referred to as a “shell” such as Unix Shells known to those of ordinary skill in the related art, or Microsoft® Windows Powershell that employs object-oriented type programming architectures such as the Microsoft®.NET framework.

Those of ordinary skill in the related art will appreciate that interfaces may include one or more GUI's, CLI's or a combination thereof. A processor may include a commercially available processor such as a Celeron, Core, or Pentium processor made by Intel Corporation®, a SPARC processor made by Sun Microsystems®, an Athlon, Sempron, Phenom, or Opteron processor made by AMD Corporation®, or it may be one of other processors that are or will become available. Some embodiments of a processor may include what is referred to as multi-core processor and/or be enabled to employ parallel processing technology in a single or multi-core configuration. For example, a multi-core architecture typically comprises two or more processor “execution cores”. In the present example, each execution core may perform as an independent processor that enables parallel execution of multiple threads. In addition, those of ordinary skill in the related field will appreciate that a processor may be configured in what is generally referred to as 32 or 64 bit architectures, or other architectural configurations now known or that may be developed in the future.

A processor typically executes an operating system, which may be, for example, a Windows type operating system from the Microsoft Corporation®; the Mac OS X operating system from Apple Computer Corp.®; a Unix® or Linux®-type operating system available from many vendors or what is referred to as an open source; another or a future operating system; or some combination thereof. An operating system interfaces with firmware and hardware in a well-known manner, and facilitates the processor in coordinating and executing the functions of various computer programs that may be written in a variety of programming languages. An operating system, typically in cooperation with a processor, coordinates and executes functions of the other components of a computer. An operating system also provides scheduling, input-output control, file and data management, memory management, and communication control and related services, all in accordance with known techniques.

Connecting components may be properly termed as computer-readable media. For example, if code or data is transmitted from a website, server, or other remote source using a coaxial cable, fiber optic cable, twisted pair, digital subscriber line (DSL), or wireless technology such as infrared, radio, or microwave signals, then the coaxial cable, fiber optic cable, twisted pair, DSL, or wireless technology are included in the definition of medium. Combinations of media are also included within the scope of computer-readable media.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

Reference numbers recited herein, in the drawings, and in the claims are solely for ease of examination of this patent application and are exemplary. The reference numbers are not intended in any way to limit the scope of the claims to the particular features having the corresponding reference numbers in the drawings.

What is claimed is:

1. A system (100) for efficient decoding of a quantum data stream, the system (100) comprising:
a) a processor (110) configured to execute computer-readable instructions; and
b) a memory component (120) operatively coupled to the processor (110), comprising:
i) a plurality of decoder modules, each decoder module configured to execute a decoding pattern corresponding to a unique harmful substructure in the quantum data stream, the unique harmful substructure comprising a plurality of variable nodes, each node corresponding to a bit, wherein the decoding pattern comprises labelling one or more nodes of the plurality of nodes as weak nodes, labelling all remaining nodes of the plurality of nodes as strong nodes, and flipping the bit of each node based on the unique harmful structure, wherein the decoding pattern is configured to increase a number of satisfied checks in the quantum data stream;
ii) computer-readable instructions for:
A) establishing a decoding threshold comprising a set number of satisfied checks;
B) identifying a plurality of unique harmful substructures in the quantum data stream;
C) executing, simultaneously, for each unique harmful substructure of the plurality of unique harmful substructures, the decoding pattern of a decoder module of the plurality of decoder modules corresponding to the unique harmful substructure of the plurality of unique harmful substructures; and
D) repeating step C until the decoding threshold is met such that all checks are satisfied or for a fixed number of iterations.

2. The system (100) of claim 1, wherein the unique harmful substructure further comprises one or more check nodes.

3. The system of claim 2, wherein each decoder module implements a two-bit flipping (TBF) decoding algorithm, wherein variable nodes and check nodes are assigned multiple discrete internal states, and bit flipping decisions are made deterministically based on these states.

4. The system (100) of claim 1, wherein the weak nodes represent nodes connected to a number of unsatisfied checks below a node strength threshold.

5. The system (100) of claim 1, wherein the strong nodes represent nodes connected to a number of unsatisfied checks above a node strength threshold.

6. The system (100) of claim 1, wherein the plurality of unique harmful substructures comprise (3,3) trapping sets, (5,5) trapping sets, (6,4) trapping sets, (8,6) trapping sets, (63,63) trapping sets, (49,49) trapping sets, or a combination thereof.

7. The system (100) of claim 1, wherein the fixed number of iterations comprises 10 to 20 iterations.

8. A computer-implemented method for efficient decoding of a quantum data stream, the method comprising:
a) establishing a decoding threshold comprising a set number of satisfied checks;
b) identifying a plurality of unique harmful substructures in the quantum data stream, each unique harmful substructure comprising a plurality of variable nodes, each node corresponding to a bit;
c) executing, simultaneously, for each unique harmful substructure of the plurality of unique harmful substructures, a decoding pattern of a decoder module of a plurality of decoder modules corresponding to the unique harmful substructure of the plurality of unique harmful substructure;
wherein the decoding pattern comprises labelling one or more nodes of the plurality of nodes as weak nodes, labelling all remaining nodes of the plurality of nodes as strong nodes, and flipping the bit of each node according to the unique harmful structure, wherein the decoding pattern is configured to increase a number of satisfied checks in the quantum data stream; and
d) repeating step c until the decoding threshold is met such that all checks are satisfied or for a fixed number of iterations.

9. The method of claim 8, wherein the unique harmful substructure further comprises one or more check nodes.

10. The method of claim 9, wherein check node updates incorporate multi-state logic to track consistency and improve correction granularity.

11. The method of claim 8, wherein the weak nodes represent nodes connected to a number of unsatisfied checks below a node strength threshold.

12. The method of claim 8, wherein the strong nodes represent nodes connected to a number of unsatisfied checks above a node strength threshold.

13. The method of claim 8, wherein the plurality of unique harmful substructures comprise (3,3) trapping sets, (5,5) trapping sets, (6,4) trapping sets, (8,6) trapping sets, (63,63) trapping sets, (49,49) trapping sets, or a combination thereof.

14. The method of claim 8, wherein the fixed number of iterations comprises 10 to 20 iterations.

15. The method of claim 8, wherein the decoding pattern comprises assigning two or more discrete state values to each variable node to represent varying levels of confidence, and flipping bits deterministically based on these states.

16. A system (500) for collective decoding of quantum low-density parity-check (QLDPC) codes, comprising:
a) a plurality of two-bit flipping (TBF) decoders (510), each configured with a distinct set of deterministic update rules and node state mappings;
b) a controller (520) configured to execute the TBF decoders (510) in parallel on a common quantum syndrome derived from quantum measurements;
c) a selection module (530) configured to determine a preferred decoding output based on a convergence metric, syndrome weight, or decoding stability; and
d) an output interface (540) configured to return the selected decoding result as the corrected codeword estimate.

17. The system (500) of claim 16, wherein the distinct set of deterministic update rules and node state mappings comprise identifying one or more weak nodes and one or more strong nodes.

18. The system (500) of claim 17, wherein the weak nodes represent nodes connected to a number of unsatisfied checks below a node strength threshold.

19. The system (500) of claim 17, wherein the strong nodes represent nodes connected to a number of unsatisfied checks above a node strength threshold.

20. The system (500) of claim 16, wherein the selection module (530) is configured to identify (3,3) trapping sets, (5,5) trapping sets, (6,4) trapping sets, (8,6) trapping sets, (63,63) trapping sets, (49,49) trapping sets, or a combination thereof.
